(19) United States
(12) Patent Application Publication
(10) Pub. No.: US 2025/0197601 A1
(43) Pub. Date: Jun. 19, 2025

(54) COMPOSITION

(71) Applicant: LMS CO., LTD., Pyeongtaek-si (KR)

(72) Inventors: Joon Ho JUNG, Pyeongtaek-si (KR); Hee Kyeong KIM, Pyeongtaek-si (KR)

(21) Appl. No.: 18/953,214

(22) Filed: Nov. 20, 2024

(30) Foreign Application Priority Data
Dec. 14, 2023 (KR) 10-2023-0181827

(51) Int. Cl. C08K 5/3417; C08K 5/1545; C08K 5/43

(52) U.S. Cl. CPC C08K 5/3417; C08K 5/1545; C08K 5/43

(57) ABSTRACT

Provided are compositions and their uses. The composition may contain three or more types of absorbents and may exhibit excellent compatibility and solubility with various solvents and resin components. The composition can be used to form a resin membrane that exhibits a wide absorption band in the infrared region and the resin membrane can function as an absorption membrane used in a variety of applications including optical filters, solid-state imaging devices, and/or infrared sensors.

### CROSS-REFERENCE TO RELATED APPLICATION(S)

This application is based on and claims priority under 35 U.S.C. 119 to Korean Patent Application No. 10-2023-0181827, filed on Dec. 14, 2023, in the Korean Intellectual Property Office, the disclosure of which is herein incorporated by reference in its entirety.

### TECHNICAL FIELD

This specification relates to compositions and their uses.

### BACKGROUND

An optical absorbent, for example, an absorbent capable of absorbing light in the infrared region can be applied to various applications. Because an image capturing device or an infrared sensor using a CCD (Charge-Coupled Device) or a CMOS (Complementary Metal-Oxide-Semiconductor) image sensor, for example, includes a silicon photodiode having sensitivity to the near-infrared region, the optical absorbent may be used for them.

There are various ways to apply these absorbents, but a method using a coating solution that mixes an absorbent dissolved in a solvent and a resin component is usually applied. Therefore, the absorbent must exhibit excellent solubility or compatibility with both the solvent and the resin component.

If the solubility or compatibility of the absorbent with the solvent or resin component is poor, the desired spectral characteristics cannot be obtained for an absorption membrane to which the absorbent is applied, or optical characteristics are deteriorated due to the phenomenon of precipitation of the absorbent within the absorption membrane. Consequently, it is a difficult task to obtain an absorbent that simultaneously exhibits excellent solubility or compatibility with various types of solvents and resin components.

In addition, for example, when a wide absorption bandwidth or other optical properties that are difficult to be obtained with a single absorbent are required, two or more types of absorbents must be applied. It is a difficult task to provide all of the two or more types of absorbents to be suitable for various types of solvents and resin components as well as to have excellent solubility or compatibility at the same time.

### SUMMARY

The object of the present specification is to disclose a composition having absorbents and exhibiting excellent compatibility and solubility with various solvents and resin components. According to an embodiment of the present invention, there is provided that a composition comprises a compound represented by Formula 1:

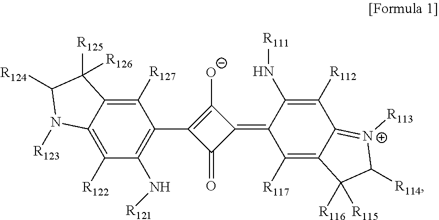

where R₁₁₁ to R₁₁₇ and R₁₂₁ to R₁₂₇ are each independently hydrogen, an alkyl group, an alkyloxy group, an alkyloxyalkyl group, an alkylcarbonyl group, an alkyloxycarbonyl group, an alkyloxyalkylcarbonyl group, or an alkylsulfonyl group where at least one of R₁₁₁ to R₁₁₇ and R₁₂₁ to R₁₂₇ is the alkyl group, the alkyloxy group, the alkyloxyalkyl group, the alkylcarbonyl group, the alkyloxycarbonyl group, the alkyloxyalkylcarbonyl group, or the alkylsulfonyl group in Formula 1; a compound represented by Formula 2:

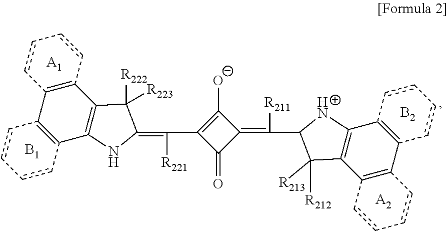

where R₂₁₁ to R₂₁₃ and R₂₂₁ to R₂₂₃ are each independently hydrogen, an alkyl group, an alkyloxy group, an alkyloxyalkyl group, an alkylcarbonyl group, an alkyloxycarbonyl group, an alkyloxyalkylcarbonyl group, or an alkylsulfonyl group where at least one is the alkyl group, the alkyloxy group, the alkyloxyalkyl group, the alkylcarbonyl group, the alkyloxycarbonyl group, the alkyloxyalkylcarbonyl group, or the alkylsulfonyl group among R₂₁₁ to R₂₁₃ and R₂₂₁ to R₂₂₃ and A₁, B₁, A₂ and B₂ are each independently a benzene structure or absent in Formula 2; and a compound represented by Formula 3:

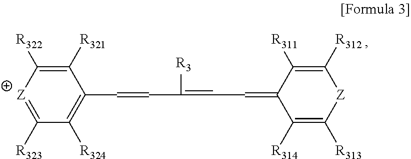

where R₃ is hydrogen or halogen; R₃₁₁, R₃₁₂, R₃₂₁ and R₃₂₃ are each independently hydrogen, an alkyl group, an alkyloxy group, an alkyloxyalkyl group, an alkylcarbonyl group, an alkyloxycarbonyl group, an alkyloxyalkylcarbonyl group, an alkylsulfonyl group, or an aryl group; R₃₁₃ and R₃₁₄ are each independently hydrogen, an alkyl group, an alkyloxy group, an alkyloxyalkyl group, an alkylcarbonyl group, an alkyloxycarbonyl group, an alkyloxyalkylcarbonyl group, an alkylsulfonyl group, or an aryl group or are connected to each other to form a benzene structure; R₃₂₃ and R₃₂₄ are each independently hydrogen, an alkyl group, an alkyloxy group, an alkyloxyalkyl group, an alkylcarbonyl group, an alkyloxycarbonyl group, an alkyloxyalkylcarbonyl group, an alkylsulfonyl group, or an aryl group or are connected to each other to form a benzene structure; at least one among R₃₁₁ to R₃₁₄ and R₃₂₁ to R₃₂₄ is an alkyl group, an alkyloxy group, an alkyloxyalkyl group, an alkylcarbonyl group, an alkyloxycarbonyl group, an alkyloxyalkylcarbonyl group, or an alkylsulfonyl group or includes Z where Z is a heteroatom in Formula 3 where a sum of A, B, and C is 30 or more and a standard deviation of A, B, and C is 15 or less where A, B, and C are defined as follows:
A: a sum of carbon numbers of the alkyl group, the alkyl group of the alkyloxy group, the alkyl group of the alkyloxyalkyl group, the alkyl group of the alkylcarbonyl group, the alkyl group of the alkyloxycarbonyl group, the alkyl group of the alkyloxyalkylcarbonyl group, and the alkyl group of the alkylsulfonyl group in Formula 1;
B: a sum of carbon numbers of the alkyl group, the alkyl group of the alkyloxy group, the alkyl group of the alkyloxyalkyl group, the alkyl group of the alkylcarbonyl group, the alkyl group of the alkyloxycarbonyl group, the alkyl group of the alkyloxyalkylcarbonyl group, and the alkyl group of the alkylsulfonyl group in Formula 2; and
C: a sum of carbon numbers of the alkyl group, the alkyl group of the alkyloxy group, the alkyl group of the alkyloxyalkyl group, the alkyl group of the alkylcarbonyl group, the alkyl group of the alkyloxycarbonyl group, the alkyl group of the alkyloxyalkylcarbonyl group, and the alkyl group of the alkylsulfonyl group in Formula 3.

In an embodiment, an average of A, B and C is in a range of 8 to 35 for the composition.

In an embodiment, a ratio A/B of A to B is in a range of 0.1 to 10, a ratio B/C of B to C is in a range of 0.1 to 10, and a ratio A/C of A to C is in a range of 0.5 to 15 for the composition.

In an embodiment, at least one among R₁₁₁ to R₁₁₇ and R₁₂₁ to R₁₂₇ is the alkyloxy group, the alkyloxyalkyl group, the alkylcarbonyl group, the alkyloxycarbonyl group, the alkyloxyalkylcarbonyl group, or the alkylsulfonyl group in Formula 1; R₂₁₁ to R₂₁₃ and R₂₂₁ to R₂₂₃ are each independently hydrogen, the alkyl group, the alkyloxy group, or the alkyloxyalkyl group upon at least one of R₂₁₁ to R₂₁₃ and R₂₂₁ to R₂₂₃ being the alkyl group, the alkyloxy group, or the alkyloxyalkyl group in Formula 2; and Z is oxygen and R₃₁₁, R₃₁₂, R₃₂₁ and R₃₂₂ are each independently hydrogen, the alkyl group, or the aryl group upon one of R₃₁₁, R₃₁₂, R₃₂₁ and R₃₂₃ being the alkyl group in Formula 3 for the composition.

In an embodiment, either A₁ or B₁ forms a benzene structure and either A₂ or B₂ forms a benzene structure for the composition.

In an embodiment, other one of A₁ and B₁ is absent and the other one of A₂ and B₂ is absent for the composition.

In an embodiment, R₃₁₃ and R₃₁₄ in Formula 3 are connected to each other to form a benzene structure and R₃₂₃ and R₃₂₄ are linked together to form a benzene structure for the composition.

In an embodiment, at least one of R₃₁₁, R₃₁₂, R₃₂₁ and R₃₂₃ is a branched alkyl group for the composition.

According to another embodiment, there is provided that a resin composition comprises a resin component; and the compositions.

In another embodiment, the resin composition further comprises a solvent.

According to yet another embodiment, there is provided that a resin membrane comprises a resin component; and the compositions.

In yet another embodiment, the resin membrane exhibits an absorption band with a bandwidth of 60 nm or wider within a wavelength range of 600 nm to 900 nm.

In yet another embodiment, T50% cut-on wavelength is within the range of 600 nm to 800 nm for the resin membrane.

In yet another embodiment, T50% cut-off wavelength is within a range of 700 nm to 900 nm for the resin membrane.

In yet another embodiment, the resin component includes at least one or more selected from a group of cycloolefin (COP) based resin, polyester resin, polyarylate resin, polysulfone resin, polyether sulfone resin, polyparaphenylene resin, polyarylene ether phosphine oxide resin, polyimide resin, polyetherimide resin, polyamideimide resin, acrylic resin, polycarbonate resin, polyethylene naphthalate resin, and silicone resin for the resin membrane.

According to yet another embodiment, there is provided that an optical filter comprises that a substrate and the resin membrane formed on one or both sides of the substrate.

In yet another embodiment, the optical filter further comprises that a dielectric membrane where the shortest wavelength exhibiting a reflectance of 50% within a wavelength range of 600 nm to 900 nm is 710 nm or longer or is absent.

According to yet another embodiment, there is provided that a solid-state image capturing device comprises the optical filter.

According to yet another embodiment, there is provided that an infrared sensor comprises the resin membrane.

### BRIEF DESCRIPTION OF THE DRAWINGS

FIGS. 1 to 3 are drawings showing exemplary structures of optical filters of the present invention.

FIGS. 4 to 7 are spectra showing the results of evaluating the transmittance of absorption membranes prepared for Embodiments or Comparative Examples.

### DETAILED DESCRIPTION

For those physical properties mentioned in the present invention where the result of measuring temperature may affect, it is measured at room temperature unless otherwise specified. The term “room temperature” used in the present invention refers to a natural temperature that is not heated or not reduced, for example, it means any temperature within the range of 10° C. to 30° C., a temperature of about 23° C. or about 25° C. In addition, in the present specification, the unit of temperature is Celsius (C) unless otherwise specified.

Among the physical properties mentioned in the present specification, in case where the measured pressure affects the result, the physical property is a physical property measured at atmospheric pressure unless specifically mentioned. The term “atmospheric pressure” is a natural pressure that is not pressurized or depressurized. It usually indicates that about 1 atmosphere of atmospheric pressure having the value of about 740 mmHg to 780 mmHg.

Among the physical properties mentioned in the present specification, in cases where humidity affects the results, the relevant physical properties are those measured at standard humidity unless otherwise specified. Humidity in a standard state means any humidity in the range of 40% to 60% relative humidity, for example, about 40% or 60% relative humidity. In the present specification, the terms “transmittance,” or “absorption rate” refer to the actual transmittance (actual transmittance), or actual absorption (actual absorption rate) confirmed within a specific wavelength or wavelength range of a predetermined region unless specifically defined otherwise. In the present specification, the terms transmittance, or absorption rate refer to transmittance, or absorption with respect to an incident angle of 0° unless specifically defined otherwise.

In the present specification, the term “average transmittance” is the result of measuring the transmittance at each wavelength while increasing the wavelength by 1 nm starting from the shortest wavelength within a certain wavelength range, and then calculating the arithmetic average of the measured transmittances unless specifically defined otherwise. For example, the average transmittance within the wavelength range of 350 nm to 360 nm may be the arithmetic mean of the transmittance measured at the wavelength of 350 nm, 351 nm, 352 nm, 353 nm, 354 nm, 355 nm, 356 nm, 357 nm, 358 nm, 359 nm, and 360 nm.

In the present specification, the term “maximum transmittance” is the maximum transmittance when the transmittance of each wavelength is measured while increasing the wavelength by 1 nm starting from the shortest wavelength within a certain wavelength range. For example, the maximum transmittance within the wavelength range of 350 nm to 360 nm may be the highest transmittance measured at the wavelength of 350 nm, 351 nm, 352 nm, 353 nm, 354 nm, 355 nm, 356 nm, 357 nm, 358 nm, 359 nm, and 360 nm.

In the present specification, the term “minimum transmittance” is the minimum transmittance when the transmittance of each wavelength is measured while increasing the wavelength by 1 nm starting from the shortest wavelength within a predetermined wavelength range. For example, the minimum transmittance within the wavelength range of 350 nm to 360 nm may be the lowest transmittance measured at the wavelength of 350 nm, 351 nm, 352 nm, 353 nm, 354 nm, 355 nm, 356 nm, 357 nm, 358 nm, 359 nm, and 360 nm. The meanings of the average transmittance, maximum transmittance, and minimum transmittance apply equally to the average absorption rate, maximum absorption rate, and minimum absorption rate, respectively, except that the transmittance is changed to the absorption rate.

In the present specification, the “incident angle” is an angle measured with respect to the normal line of the surface to be evaluated. For example, “the transmittance at an incident angle of 0° of an optical filter” means the transmittance of light incident in a direction substantially parallel to the normal line of the surface of the optical filter. In addition, for example, an incident angle of 40° is a value for incident light forming an angle of substantially 40° in a clockwise or counterclockwise direction with the normal. This definition of the incident angle applies equally to other characteristics such as transmittance.

The present specification discloses compositions. The term “composition” refers to a mixture of two or more components in the present specification.

In the present specification, the term “absorbent composition” may be a composition made of absorbents, that is, a mixture of only two or more types of absorbents. For example, the term “absorbent composition” refers to a mixture of two or three or more types of absorbents with different chemical structures.

In the present specification, the term “absorbent” refers to a compound that exhibits lower transmittance at any specific wavelength compared to other wavelengths. In the present specification, the term “resin composition” refers to a mixture containing a resin component and other components.

In one example, the absorbent composition may include a compound of Formula 1, a compound of Formula 2, and a compound of Formula 3. Compounds of Formulas 1 to 3 have different structures.

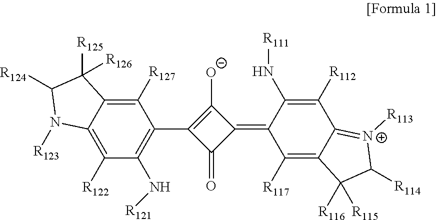

In Formula 1, R₁₁₁ to R₁₁₇ and R₁₂₁ to R₁₂₇ may be each independently hydrogen, an alkyl group, an alkyloxy group, an alkyloxyalkyl group, an alkylcarbonyl group, an alkyloxycarbonyl group, an alkyloxyalkylcarbonyl group, or an alkylsulfonyl group. In Formula 1, the alkyl group, an alkyl group of the alkyloxy group, an alkyl group of the alkyloxyalkyl group, an alkyl group of the alkylcarbonyl group, an alkyl group of the alkyloxycarbonyl group, an alkyl group of the alkyloxyalkylcarbonyl group and an alkyl group of the alkylsulfonyl group may each independently be an alkyl group having 1 to 20 carbon numbers, 1 to 16 carbon numbers, 1 to 12 carbon numbers, 1 to 8 carbon numbers, or 1 to 4 carbon numbers. Additionally, the alkyl group may be a straight-chain, a branched-chain, or a cyclic. The alkyl group may be arbitrarily substituted with one or more substituents or may be an unsubstituted alkyl group.

In Formula 1, at least one of R₁₁₁ to R₁₁₇ and R₁₂₁ to R₁₂₇ may be the alkyl group, the alkyloxy group, the alkyloxyalkyl group, the alkylcarbonyl group, the alkyloxycarbonyl group, the alkyloxyalkylcarbonyl group, or the alkylsulfonyl group. In a suitable example of Formula 1, R₁₁₁ and R₁₂₁ may each independently be the alkyloxy group, the alkylcarbonyl group, the alkyloxycarbonyl group, or the alkylsulfonyl group. In a suitable example of Formula 1, R₁₁₂, R₁₂₂, R₁₁₇ and R₁₂₇ may each independently be hydrogen or the alkyl group or may be hydrogen. In a suitable example of Formula 1, R₁₁₃ and R₁₂₃ may each independently be the alkyl group or the alkyloxy group. In a suitable example of Formula 1, R₁₁₄ to R₁₁₆ and R₁₂₄ to R₁₂₆ may each independently be the alkyl group, the alkyloxy group, or the alkyl group.

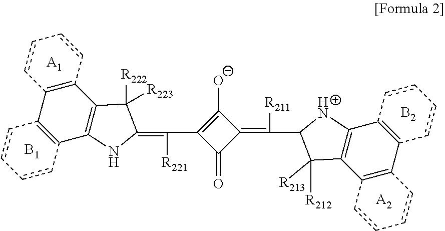

In Formula 2, R₂₁₁ to R₂₁₃ and R₂₂₁ to R₂₂₃ may each independently be hydrogen, an alkyl group, an alkyloxy group, an alkyloxyalkyl group, an alkylcarbonyl group, an alkyloxycarbonyl group, an alkyloxyalkylcarbonyl group, or an alkylsulfonyl group. In Formula 2, details as to the alkyl group, an alkyl group of the alkyloxy group, an alkyl group of the alkyloxyalkyl group, an alkyl group of the alkylcarbonyl group, an alkyl group of the alkyloxycarbonyl group, an alkyl group of the alkyloxyalkylcarbonyl group, and an alkyl group of the alkylsulfonyl group are the same as those in Formula 1. In Formula 2, at least one of R₂₁₁ to R₂₁₃ and R₂₂₁ to R₂₂₃ may be the alkyl group, the alkyloxy group, the alkyloxyalkyl group, the alkylcarbonyl group, the alkyloxycarbonyl group, the alkyloxyalkylcarbonyl group, or the alkylsulfonyl group.

In Formula 2, A₁, B₁, A₂ and B₂ each independently are a benzene structure or do not exist. When a benzene structure is formed above, the benzene structure may be in substituted or unsubstituted state.

In a suitable example of Formula 2, R₂₁₁ and R₂₂₁ may each independently be the alkyl group, the alkyloxy group, or the alkyloxyalkyl group. For example, they may be the alkyl group or the alkyloxyalkyl group. In a suitable example of Formula 2, R₂₁₂, R₂₁₃, R₂₂₂ and R₂₂₃ may each independently be hydrogen or the alkyl group. For example, they may be the alkyl group.

In a suitable example of Formula 2, at least one of A₁ and B₁ may be a benzene structure. For example, one of A₁ and B₁ may be a benzene structure and the other may not exist. In a suitable example of Formula 2, at least one of A₂ and B₂ may be a benzene structure. For example, one of A₂ and B₂ may be a benzene structure and the other may not exist.

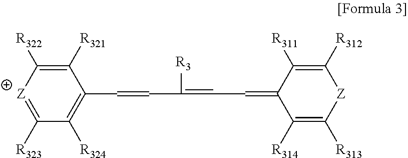

In Formula 3, R₃ may be hydrogen or halogen. For example, it may be hydrogen, chlorine, fluorine, or iodine. In Formula 3, R₃₁₁, R₃₁₂, R₃₂₁ and R₃₂₂ may be each independently hydrogen, an alkyl group, an alkyloxy group, an alkyloxyalkyl group, an alkylcarbonyl group, an alkyloxycarbonyl group, an alkyloxyalkylcarbonyl group, an alkylsulfonyl group or an aryl group. In Formula 3, R₃₁₃ and R₃₁₄ may be each independently hydrogen, the alkyl group, the alkyloxy group, the alkyloxyalkyl group, the alkylcarbonyl group, the alkyloxycarbonyl group, the alkyloxyalkylcarbonyl group, the alkylsulfonyl group, or the aryl group, or they may be connected to each other to form a benzene structure. In Formula 3, R₃₂₃ and R₃₂₄ may be each independently hydrogen, the alkyl group, the alkyloxy group, the alkyloxyalkyl group, the alkylcarbonyl group, the alkyloxycarbonyl group, the alkyloxyalkylcarbonyl group, the alkylsulfonyl group, or the aryl group, or they may be connected to each other to form the benzene structure.

In Formula 3, Z may be a heteroatom, that is, an atom other than carbon and hydrogen. It may be, for example, an oxygen, a nitrogen or a sulfur atom. In Formula 3, details as to the alkyl group, an alkyl group of the alkyloxy group, an alkyl group of the alkyloxyalkyl group, an alkyl group of the alkylcarbonyl group, an alkyl group of the alkyloxycarbonyl group, an alkyl group of the alkyloxyalkylcarbonyl group, and an alkyl group of the alkylsulfonyl group are the same as those in Formula 1.

In Formula 3, an aryl group is a monovalent residue derived from one molecule of benzene, a compound with a structure of two or more benzene molecules, or its derivative. The range of compounds having a structure where two or more benzenes are bonded as described above includes structures where two or more benzenes are connected by a linker such as phenylbenzene or diphenylmethane; a structure where two benzenes are bonded while sharing two carbon atoms such as naphthalene; and spiro compounds where two benzenes are bonded while sharing one carbon atom. The aryl group may be an aryl group having 6 to 30 carbon numbers, 6 to 24 carbon numbers, 6 to 18 carbon numbers, 6 to 12 carbon numbers, 6 to 10 carbon numbers, or 6 to 8 carbon numbers. These aryl groups may be in substituted or unsubstituted state.

In a suitable example of Formula 3, R₃₁₁, R₃₁₂, R₃₂₁ and R₃₂₂ may each independently be hydrogen, the alkyl group, or the alkyloxy group. In a suitable example of Formula 3, one of R₃₁₁ and R₃₁₂ may be hydrogen and the other may be the alkyl group or the alkyloxy group. At this time, the alkyl group or the alkyl group of the alkyloxy group may be a branched alkyl group.

In a suitable example of Formula 3, one of R₃₂₁ and R₃₂₂ may be hydrogen and the other may be the alkyl group or the alkyloxy group. At this time, the alkyl group or the alkyl group of the alkyloxy group may be a branched alkyl group.

In Formula 3, when R₃₁₃ and R₃₁₄ are not connected to each other to form a benzene structure, each may independently be hydrogen, the alkyl group, or the aryl group. In Formula 3, when R₃₂₃ and R₃₂₄ are not connected to each other to form the benzene structure, each may independently be hydrogen, the alkyl group, or the aryl group. In Formula 3, any one pair of R₃₁₃ and R₃₁₄ and R₃₂₃ and R₃₂₄ may be connected to each other to form a benzene structure. For example, when all of R₃₁₃ and R₃₁₄ and R₃₂₃ and R₃₂₄ form the benzene structure, the compound of Formula 3 may be represented by Formula 4.

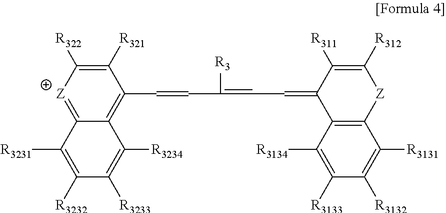

In Formula 4, R₃, R₃₁₁, R₃₁₂, R₃₂₁, R₃₂₂ and Z are the same as R₃, R₃₁₁, R₃₁₂, R₃₂₁, R₃₂₂ and Z in Formula 3, respectively. In Formula 4, R₃₁₃₁ to R₃₁₃₄ and R₃₂₃₁ to R₃₂₃₄ may be each independently hydrogen, an alkyl group, an alkyloxy group, an alkyloxyalkyl group, an alkylcarbonyl group, an alkyloxycarbonyl group, an alkyloxyalkylcarbonyl group, or an alkylsulfonyl group. They may be, for example, hydrogen, the alkyl group, the alkyloxy group, or the alkyloxyalkyl group. In Formula 4, details as to the alkyl group, an alkyl group of the alkyloxy group, an alkyl group of the alkyloxyalkyl group, an alkyl group of the alkylcarbonyl group, an alkyl group of the alkyloxycarbonyl group, an alkyl group of the alkyloxyalkylcarbonyl group, and an alkyl group of the alkylsulfonyl group are the same as those in Formula 1.

In one example, the absorbent composition may include the compound of Formula 1, the compound of Formula 2, and the compound of Formula 3. To achieve the desired optical properties and to ensure appropriate solubility and compatibility with various solvents and resins, mixing ways for the compounds of Formulas 1 to 3 may be adjusted. For example, numbers of A to C below for the mixing ways can be adjusted:
A: Sum of carbon numbers of the alkyl group, the alkyl group of the alkyloxy group, the alkyl group of the alkyloxyalkyl group, the alkyl group of the alkylcarbonyl group, the alkyl group of the alkyloxycarbonyl group, the alkyl group of the alkyloxyalkylcarbonyl group, and the alkyl group of the alkylsulfonyl group in Formula 1;
B: Sum of carbon numbers of the alkyl group, the alkyl group of the alkyloxy group, the alkyl group of the alkyloxyalkyl group, the alkyl group of the alkylcarbonyl group, the alkyl group of the alkyloxycarbonyl group, the alkyl group of the alkyloxyalkylcarbonyl group, and the alkyl group of the alkylsulfonyl group in Formula 2; and
C: Sum of carbon numbers of the alkyl group, the alkyl group of the alkyloxy group, the alkyl group of the alkyloxyalkyl group, the alkyl group of the alkylcarbonyl group, the alkyl group of the alkyloxycarbonyl group, the alkyl group of the alkyloxyalkylcarbonyl group, and the alkyl group of the alkylsulfonyl group in Formula 3.

In other words, A is a total sum of carbon numbers of the alkyl group, the alkyl group of an alkyloxy group, the alkyl group of the alkyloxyalkyl group (two alkyl groups), the alkyl group of the alkylcarbonyl group, the alkyl group of the alkyloxycarbonyl group, the alkyl group of the alkyloxyalkylcarbonyl group (two alkyl groups), and the alkyl group of the alkylsulfonyl group present at R₁₁₁ to R₁₁₇ and R₁₂₁ to R₁₂₇ in Formula 1. In addition, B is a total sum of carbon numbers of the alkyl group, the alkyl group of an alkyloxy group, the alkyl group of the alkyloxyalkyl group (two alkyl groups), the alkyl group of the alkylcarbonyl group, the alkyl group of the alkyloxycarbonyl group, the alkyl group of the alkyloxyalkylcarbonyl group (two alkyl groups), and the alkyl group of the alkylsulfonyl group present at R₂₁₁ to R₂₁₃ and R₂₂₁ to R₂₂₃ in Formula 2. If in Formula 2, A₁, B₁, A₂ and/or B₂ is a benzene structure and if the benzene structure is substituted with the alkyl group, the alkyloxy group, the alkyloxyalkyl group, the alkylcarbonyl group, the alkyloxycarbonyl group, the alkyloxyalkylcarbonyl group, or the alkylsulfonyl group, the carbon number of the alkyl group of the corresponding substituent is included for calculating B.

In addition, C is a total sum of carbon numbers of the alkyl group, the alkyl group of an alkyloxy group, the alkyl group of the alkyloxyalkyl group (two alkyl groups), the alkyl group of the alkylcarbonyl group, the alkyl group of the alkyloxycarbonyl group, the alkyl group of the alkyloxyalkylcarbonyl group (two alkyl groups), and the alkyl group of the alkylsulfonyl group present at R₃₁₁ to R₃₁₄ and R₃₂₁ to R₃₂₄ in Formula 3. If in Formula 3, R₃₁₄ and R₃₁₃ and/or R₃₂₃ and R₃₂₄ forms a benzene structure and if the substituents of the benzene structure (for example, R₃₁₃₁ to R₃₁₃₄ and R₃₂₃₁ to R₃₂₃₄ in Formula 4) are the alkyl group, the alkyloxy group, the alkyloxyalkyl group, the alkylcarbonyl group, the alkyloxycarbonyl group, the alkyloxyalkylcarbonyl group, or the alkylsulfonyl group or any one or more of R₃₁₁ to R₃₁₄ and R₃₂₁ to R₃₂₄ in Formula 3 is the aryl group and the aryl group is the alkyl group, the alkyloxy group, the alkyloxyalkyl group, the alkylcarbonyl group, the alkyloxycarbonyl group, the alkyloxyalkylcarbonyl group, or the alkylsulfonyl group, the carbon number of the alkyl group of the corresponding substituent is included for calculating C. The lower limit of the sum of A, B, and C may be around 30, 35, 40, 45, 50, 55, or 60, and the upper limit may be around 200, 180, 160, 140, 120, 100, 95, 90, 85, 80, 75, 70, 65, 60, 55, 50, 45 or 40. The sum of A, B and C may be within a range equal to or exceeding any one of the lower limits described above or it may be within a range equal to or exceeding any one of the lower limits and equal to or below any one of the upper limits described above. Within the range, the absorbent composition can achieve the desired optical properties and ensure appropriate solubility and compatibility with various solvents and resins.

The standard deviation of A, B, and C may also be within a certain range. The standard deviation can be calculated as [{(AV)²+(BV)²+(CV)²}/3]^{0.5}. The lower limit of the standard deviation may be 0, 2, 4, 6, 8, 10, or 12 and the upper limit may be 50, 45, 40, 35, 30, 25, 20, 15, 10, 8, 6, or 4. The standard deviation of A, B and C may be within a range equal to or exceeding any one of the lower limits; within a range equal to or below any one of the upper limits; or within a range equal to or exceeding any one of the lower limits and equal to or below any one of the upper limits described above. Within this range, the absorbent composition can achieve the desired optical properties and ensure appropriate solubility and compatibility with various solvents and resins.

The lower limit of the average (arithmetic mean) of A, B, and C may be around 6, 8, 10, 12, 14, 16, 18, or 20, and the upper limit may be around 35, 33, 31, 29, 27, 25, 23, 21, 19, 17, 15, or 12. The average (arithmetic mean) of A, B and C may be within a range equal to or exceeding any one of the lower limits described above; within a range equal to or below any of the upper limits; or within a range equal to or exceeding any one of the lower limits and equal to or below any one of the upper limits described above. Within this range, the absorbent composition can achieve the desired optical properties and ensure appropriate solubility and compatibility with various solvents and resins.

The ratio A/B of A to B can be controlled. The lower limit of A/B may be 0.1, 0.3, 0.5, 0.7, 0.9, 1, 1.5, 2, 2.5 or 2.8 and the upper limit may be 10, 9, 8, 7, 6, 5, 4, 3, 2, 1.5, or 1. The ratio A/B may be within a range equal to or exceeding any one of the lower limits; within a range equal to or below any of the upper limits; or within a range equal to or exceeding any one of the lower limits and equal to or below any one of the upper limits described above. Within this range, the absorbent composition can achieve the desired optical properties and ensure appropriate solubility and compatibility with various solvents and resins.

The ratio B/C of B to C can be controlled. The lower limit of B/C may be 0.1, 0.3, 0.5, 0.7, 0.9, 1, 1.2, 1.4, 1.6, 1.8 or 2, and the upper limit may be 10, 9, 8, 7, 6, 5, 4, 3, 2.5, or 2. The ratio B/C may be within a range equal to or exceeding any one of the lower limits; within a range equal to or below any of the upper limits; or within a range equal to or exceeding any one of the lower limits and equal to or below any one of the upper limits described above. Within this range, the absorbent composition can achieve the desired optical properties and ensure appropriate solubility and compatibility with various solvents and resins.

The ratio A/C of A to C can be controlled. The lower limit of the A/C may be about 0.5, 1, 1.5, 2, 2.5, 3, 3.5, or 4, and the upper limit may be about 15, 13, 11, 9, 7, 5, or 3. The ratio A/C may be within a range equal to or exceeding any one of the lower limits; within a range equal to or below any of the upper limits; or within a range equal to or exceeding any one of the lower limits and equal to or below any one of the upper limits described above. Within this range, the absorbent composition can achieve the desired optical properties and ensure appropriate solubility and compatibility with various solvents and resins.

The structures of Formulas 1 to 3 can be controlled to more efficiently ensure the desired effect. For example, in the above mixture, at least one of R₁₁₁ to R₁₁₇ and R₁₂₁ to R₁₂₇ of Formula 1 may be the alkyloxy group, the alkyloxyalkyl group, the alkylcarbonyl group, the alkyloxycarbonyl group, the alkyloxyalkylcarbonyl group, or the alkylsulfonyl group. For example, it may be the alkyloxycarbonyl group, the alkyloxyalkyl group, the alkyloxyalkylcarbonyl group, or the alkylsulfonyl group. In a more appropriate example, it may be the alkyloxycarbonyl group or the alkyloxyalkylcarbonyl group.

For example, in Formula 1, at least one of R₁₁₁, R₁₁₃, R₁₂₁ and R₁₂₃ may be the alkyloxy group, the alkyloxyalkyl group, the alkylcarbonyl group, the alkyloxycarbonyl group, the alkyloxyalkylcarbonyl group, or the alkylsulfonyl group. It may be, for example, the alkyloxycarbonyl group, the alkyloxyalkyl group, the alkyloxyalkylcarbonyl group, or the alkylsulfonyl group. In a more appropriate example, it may be the alkyloxycarbonyl group or the alkyloxyalkylcarbonyl group.

For example, in the above mixture, R₂₁₁ to R₂₁₃ and R₂₂₁ to R₂₂₃ of Formula 2 may be each independently hydrogen, an alkyl group, an alkyloxy group, or an alkyloxyalkyl group and at least one of them may be the alkyl group, the alkyloxy group, or the alkyloxyalkyl group. Additionally, in an appropriate example, R₂₁₁ to R₂₁₃ and R₂₂₁ to R₂₂₃ in Formula 2 may each independently be hydrogen, the alkyl group, or the alkyloxyalkyl group. For example, they may be the alkyl group or the alkyloxyalkyl group.

Additionally, in a suitable example, in Formula 2, either or both of A₁ and B₁ may form a benzene structure and either or both of A₂ and B₂ may form a benzene structure. Additionally, in a suitable example, in Formula 2, one of A₁ and B₁ forms a benzene structure and the other may not be present and either A₂ and B₂ forms a benzene structure and the other may not be present.

For example, in the above mixture, Z in Formula 3 may be oxygen. For example, in the above mixture, R₃₁₁, R₃₁₂, R₃₂₁ and R₃₂₂ of Formula 3 may be each independently hydrogen, an alkyl group or an aryl group, but at least one of R₃₁₁, R₃₁₂, R₃₂₁ and R₃₂₃ may be the alkyl group. This alkyl group may be a branched alkyl group. For example, in Formula 3, at least one of R₃₁₁, R₃₁₂, R₃₂₁ and R₃₂₂ may be the branched alkyl group. Additionally, in Formula 3, a pair of R₃₁₃ and R₃₁₄ and/or a pair of R₃₂₃ and R₃₂₄ may be connected to each other to form a benzene structure. For example, the compound of Formula 3 may have the structure of Formula 4.

By including the above three types of compounds having such formation, an absorbent composition exhibiting desired properties can be provided. There is no particular limitation on the ratio between the three types of compounds in the absorbent composition. In other words, the ratio between the compounds can be adjusted considering the desired optical properties.

For example, the lower limit of the ratio of the compound of Formula 1 for the absorbent composition may be 5% by weight, 10% by weight, 15% by weight, 20% by weight, 25% by weight, 30% by weight, 35% by weight, or 40% by weight and the upper limit may be 80% by weight, 75% by weight, 70% by weight, 65% by weight, 60% by weight, 55% by weight, 50% by weight, or 45% by weight. The ratio may be within a range equal to or exceeding any one of the lower limits; within a range equal to or below any one of the upper limits; or within a range equal to or exceeding any one of the lower limits and equal to or below any one of the upper limits described above. These ratios may be changed considering the desired effect. For example, the lower limit of the ratio of the compound of Formula 2 to 100 parts by weight of the compound of Formula 1 for the absorbent composition may be about 10 parts by weight, 30 parts by weight, 50 parts by weight, or 70 parts by weight, and the upper limit may be about 200 parts by weight, 180 parts by weight, 160 parts by weight, 140 parts by weight, 120 parts by weight, 100 parts by weight, or 80 parts by weight. The ratio may be within a range equal to or exceeding any one of the lower limits; within a range equal to or below any of the upper limits; or within a range equal to or exceeding any one of the lower limits and equal to or below any one of the upper limits described above. These ratios may be changed considering the desired effect.

For example, the lower limit of the ratio of the compound of Formula 3 to 100 parts by weight of the compound of Formula 1 for the absorbent composition may be about 10 parts by weight, 30 parts by weight, 50 parts by weight, or 70 parts by weight, and the upper limit is It may be about 200 parts by weight, 180 parts by weight, 160 parts by weight, 140 parts by weight, 120 parts by weight, 100 parts by weight, or 80 parts by weight. The ratio may within a range equal to or exceeding any one of the lower limits; within a range equal to or below any of the upper limits; or within a range equal to or exceeding any one of the lower limits and equal to or below any one of the upper limits described above. These ratios may be changed considering the desired effect.

If necessary to obtain the desired effect, the ratio of the compounds of Formulas 1 to 3 relative to the total absorbents included in the absorbent composition may be adjusted. For example, the lower limit of the ratio of the total weight of the compounds of Formulas 1 to 3 with respect to the weight of all absorbent components included in the absorbent composition may be 50% by weight, 55% by weight, 60% by weight, 65% by weight, 70% by weight, 75% by weight, 80% by weight, 85% by weight, 90% by weight, or 95% by weight and the upper limit may be about 100% by weight, 95% by weight, 90% by weight, or 85% by weight. The ratio may be within a range equal to or exceeding any one of the lower limits; within a range equal to or below any of the upper limits; or within a range equal to or exceeding any one of the lower limits and equal to or below any one of the upper limits described above. These ratios may be changed considering the desired effect.

The absorbent composition may contain other absorbents as required in addition to the compounds of formulas 1 to 3 described above. Additionally, the absorbent composition may include an anion as a component of the absorbent. This anion may be, for example, a counter ion of the compound of Formula 3 above. Examples of the anions may be exemplified to include known anions generated during the absorbent synthesis process such as halogen ions, hexafluoroantimonic acid ions (SbF₆⁻), perchlorate ions, thiocyanate ions (SCN⁻), hexafluorophosphate ion (PF₆⁻), phosphate ion, bis trifluoromethanesulfonyl imide ion, tetrakispentafluorophenyl borate ion, tetrakiss 3,5-bis trifluoromethyl phenyl borate ion, tetrafluoroborate ion (BF₄⁻), trifluoromethylcarboxylic acid ion, alkylsulfonic acid ion, benzenesulfonic acid ion, toluenesulfonic acid ion, benzenecarboxylic acid ion, alkylcarboxylic acid ion, hydrofluoroborate ion, and/or tetraphenylboric acid ion, but are not limited to.

The present specification also discloses resin compositions. The resin composition may include a resin component and other components where the other component may be the absorbent composition described above.

For example, the resin component may serve as a binder. There is no particular limitation on the type of resin component applied in this case and publicly known resin components used to form an absorption membrane, for example, a near-infrared absorption membrane, can be applied. The absorbent composition may exhibit appropriate compatibility or solubility with the various known resin components.

Examples of resin components may include cycloolefin (COP) based resin, polyester resin, polyarylate resin, polysulfone resin, polyether sulfone resin, polyparaphenylene resin, polyarylene ether phosphine oxide resin, polyimide resin, polyetherimide resin, polyamidoimide resin, acrylic resin, polycarbonate resin, polyethylene naphthalate resin, or silicone resin, or various other organic resins or organic-inorganic hybrid resins, but are not limited to. When the resin component is applied, there is no particular limitation for its ratio. For example, the lower limit of the ratio of the resin component in the resin composition may be 50% by weight, 55% by weight, 60% by weight, 65% by weight, 70% by weight, 75% by weight, 80% by weight, 85% by weight, It may be about 90% by weight or 95% by weight and the upper limit may be about 100% by weight, 95% by weight, 90% by weight, or 85% by weight. The ratio may be within a range equal to or exceeding any one of the lower limits; within a range equal to or below any of the upper limits; or within a range equal to or exceeding any one of the lower limits and equal to or below any one of the upper limits described above. These ratios may be changed considering the desired effect.

For the resin composition, the lower limit of the ratio of the absorbent composition to 100 parts by weight of the resin component may be about 0.5 parts by weight, 1 part by weight, 1.5 parts by weight, 2 parts by weight, 2.5 parts by weight, 3 parts by weight, 3.5 parts by weight, 4 parts by weight. It may be about 50 parts by weight, 4.5 parts by weight, 5 parts by weight, 5.5 parts by weight, 6 parts by weight, 6.5 parts by weight, or 7 parts by weight and the upper limit may be about 50 parts by weight, 45 parts by weight, 40 parts by weight, 35 parts by weight, It may be about 30 parts by weight, 25 parts by weight, 20 parts by weight, 15 parts by weight, or 10 parts by weight. The ratio may be within a range equal to or exceeding any one of the lower limits; within a range equal to or below any of the upper limits; or within a range equal to or exceeding any one of the lower limits and equal to or below any one of the upper limits described above. These ratios may be changed considering the desired effect.

For example, the resin composition may further include a solvent where the absorbent composition and/or the resin component are dispersed. There is no particular limitation on the type of solvent applied in this case and any publicly known solvent used to form an absorption membrane, for example, a near-infrared absorption membrane, can be applied. The absorbent component may exhibit appropriate compatibility or solubility in various known solvents.

Examples of solvents include, but are not limited to, cyclohexanone, toluene, methyl ethyl ketone, methyl isobutyl ketone, chlorobenzene, or xylene. When a solvent is applied, there is no particular limitation to the ratio and the ratio can be adjusted within a range that allows appropriate dispersion of the resin component and/or absorbent composition. The resin composition may contain other necessary components in addition to the components described above.

The present specification also relates to the use of the absorbent composition and/or resin composition. For example, the present specification discloses a resin membrane (absorption membrane) containing the above resin component and the above absorbent composition.

Specific details about the resin component and absorbent composition forming the resin membrane are as described above. For example, the lower limit of the ratio of the resin component for the resin membrane may be 50% by weight, 55% by weight, 60% by weight, 65% by weight, 70% by weight, 75% by weight, 80% by weight, 85% by weight, 90% by weight, or 95% by weight and the upper limit may be about 100% by weight, 95% by weight, 90% by weight, or 85% by weight. The ratio may be within a range equal to or exceeding any one of the lower limits; within a range equal to or below any of the upper limits; or within a range equal to or exceeding any one of the lower limits and equal to or below any one of the upper limits described above. These ratios may be changed considering the desired effect.

The lower limit of the ratio of the absorbent composition to 100 parts by weight of the resin component for the resin membrane may be about 0.5 parts by weight, 1 part by weight, 1.5 parts by weight, 2 parts by weight, 2.5 parts by weight, 3 parts by weight, 3.5 parts by weight, 4 parts by weight, 4.5 parts by weight, 5 parts by weight, 5.5 parts by weight, 6 parts by weight, 6.5 parts by weight, or 7 parts by weight and the upper limit may be about 50 parts by weight, 45 parts by weight, 40 parts by weight, 35 parts by weight, 30 parts by weight, 25 parts by weight, 20 parts by weight, 15 parts by weight, or 10 parts by weight. The ratio may be within a range equal to or exceeding any one of the lower limits; within a range equal to or below any of the upper limits; or within a range equal to or exceeding any one of the lower limits and equal to or below any one of the upper limits described above. These ratios may be changed considering the desired effect.

The resin membrane may be an absorption membrane capable of absorbing light within a predetermined range of wavelengths. In one example, the resin membrane may be an infrared absorption membrane or a near-infrared absorption membrane.

For example, such a resin membrane may exhibit absorption characteristics in at least a portion of the wavelength range within a range of about 600 nm to 900 nm. For example, the resin membrane can have a relatively wide bandwidth within the wavelength range of 600 nm to 900 nm through application of the above-described absorbent composition and can have absorption characteristics for longer wavelengths.

Due to these characteristics, the absorption membrane can be applied to various devices such as an optical filter and an infrared sensor to prevent shift phenomenon with respect to the incident angle. In addition, when a dielectric membrane is applied to the optical filter or infrared sensor, etc., the reflection characteristics of the dielectric membrane can be adjusted to prevent defects such as so-called petal flare and thus, the number of layers of the dielectric membrane can be reduced. By doing so, an advantage for manufacturing can also be achieved.

Therefore, in one example, the absorption membrane may exhibit an absorption band with a bandwidth of 60 nm or more within the wavelength range of 600 nm to 900 nm. The absorption band may refer to a region showing a transmittance of approximately 70% or less in the transmittance curve of the absorption membrane.

The bandwidth refers to the difference between the longest wavelength representing a transmittance of 20% and the shortest wavelength representing a transmittance of 20% in the wavelength region of 600 nm to 900 nm of the transmittance curve of the absorption membrane. In this case, the lower limit of the bandwidth may be about 60 nm, 70 nm, 80 nm, 90 nm, 100 nm, 110 nm, 120 nm, 130 nm, 140 nm, 150 nm, or 155 nm and the upper limit may be about 1,000 nm, 950 nm, 900 nm, 850 nm, 800 nm, 750 nm, 700 nm, 650 nm, 600 nm, 550 nm, 500 nm, 450 nm, 400 nm, 350 nm, 300 nm, 250 nm, 200 nm, 190 nm, 180 nm, 170 nm, 160 nm, 150 nm, 140 nm, 130 nm, 120 nm, 110 nm, or 100 nm. The bandwidth may be within a range equal to or exceeding any one of the lower limits; within a range equal to or below any of the upper limits; or within a range equal to or exceeding any one of the lower limits and equal to or below any one of the upper limits described above.

As a different bandwidth, the difference between the longest wavelength representing a transmittance of 50% and the shortest wavelength representing a transmittance of 50% within the wavelength region of 600 nm to 900 nm of the transmittance curve of the absorption membrane can also be adjusted. In this case, the lower limit of the bandwidth may be about 60 nm, 70 nm, 80 nm, 90 nm, 100 nm, 110 nm, 120 nm, 130 nm, 140 nm, 150 nm, 155 nm, 160 nm, 165 nm, 170 nm, 175 nm, 180 nm, 185 nm, 190 nm or 195 nm and the upper limit may be about 1,000 nm, 950 nm, 900 nm, 850 nm, 800 nm, 750 nm, 700 nm, 650 nm, 600 nm., 550 nm, 500 nm, 450 nm, 400 nm, 350 nm, 300 nm, 250 nm, 200 nm, 190 nm, 180 nm, 170 nm, 160 nm, 150 nm, 140 nm, 130 nm, 120 nm, 110 nm, or 100 nm. The bandwidth may be within a range equal to or exceeding any one of the lower limits; within a range equal to or below any of the upper limits; or within a range equal to or exceeding any one of the lower limits and equal to or below any one of the upper limits described above.

Additionally, the T50% cut-on wavelength of the absorption membrane may be within a predetermined range. The lower limit of the T50% cut-on wavelength may be about 600 nm, 610 nm, 620 nm, 630 nm, 640 nm, or 650 nm and the upper limit may be about 800 nm, 790 nm, 780 nm, 770 nm, 760 nm, or750 nm. The T50% cut-on wavelength may be within a range equal to or exceeding any one of the lower limits and equal to or below any one of the upper limits described above. The T50% cut-on wavelength refers to the shortest wavelength showing a transmittance of 50% in the wavelength range of 600 nm to 900 nm of the transmittance curve of the absorption membrane.

The T50% cut-off wavelength of the absorption membrane may be within a predetermined range. The T50% Cut-off wavelength may be a longer wavelength than the T50% cut-on wavelength. The lower limit of the T50% cut-off wavelength may be about 700 nm, 720 nm, 740 nm, 760 nm, 780 nm, or 800 nm and the upper limit may be about 900 nm, 880 nm, 860 nm, 840 nm, 820 nm, 810 nm or 800 nm for another examples. The T50% cut-off wavelength may be within a range equal to or exceeding any one of the lower limits and equal to or below any one of the upper limits described above. The T50% cut-off wavelength refers to the longest wavelength showing a transmittance of 50% in the wavelength range of 600 nm to 900 nm of the transmittance curve of the absorbing membrane.

Through the absorption properties, the absorption membrane can be applied to various devices such as an optical filter and an infrared sensor to efficiently achieve the desired properties. The absorption membrane can be formed in a publicly known manner as long as the absorbent composition is applied. For example, the absorbent composition or resin composition may be coated in an appropriate manner, and if necessary, a curing or drying process may be performed to form the absorption membrane.

There is no particular limitation on the thickness of the absorption membrane. The thickness can be adjusted considering desired characteristics. In one example, the absorption membrane may have a thickness of approximately 0.1 μm to 20 μm.

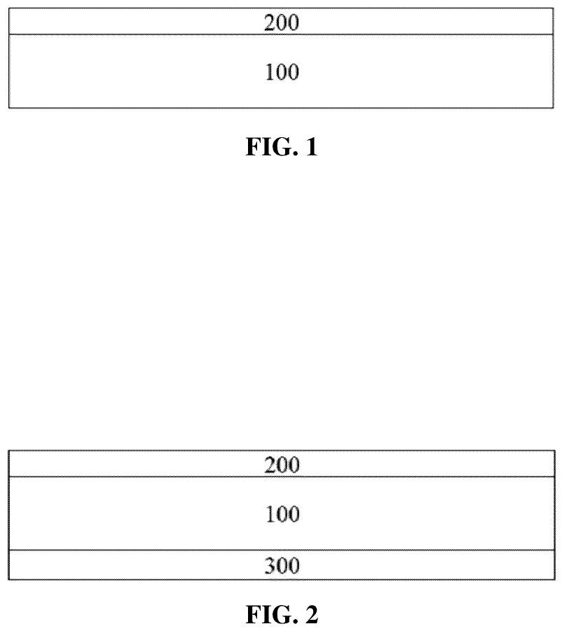

The present specification also discloses an optical filter. The optical filter may include a substrate and the absorption membrane formed on one or both sides of the substrate layer. FIG. 1 is an example of the optical filter illustrating the absorption membrane 200 is formed on one side of the substrate 100.

Such an optical filter can exhibit excellent performance by including the above-described absorption membrane. For example, the optical filter can efficiently and accurately block unnecessary infrared light and implement a visible light transmission band with high transmittance.

There is no particular limitation on the type of transparent substrate applied to the optical filter. A publicly known transparent substrate for the optical filter can be used. In one example, the substrate may be a so-called infrared absorbing substrate. An infrared absorbing substrate is a substrate that exhibits absorption characteristics in at least a portion of the infrared region. A so-called blue glass, which exhibits the above properties by including copper, is a representative example of the infrared absorbing substrate. Such an infrared absorbing substrate is useful in constructing an optical filter that blocks light in the infrared region, but due to the absorption characteristic, it is disadvantageous in terms of ensuring high transmittance in the visible light region and is also disadvantageous in terms of durability. By selecting the infrared absorbing substrate and combining it with the specific absorption membrane, an optical filter that efficiently blocks desired light, exhibits high transmittance characteristics in the visible light region, and has excellent durability can be provided.

As for the infrared absorbing substrate, a substrate exhibiting an average transmittance of 75% or higher within a wavelength range of 425 nm to 560 nm can be used. In another examples, the average transmittance may be within the range of 77% or more, 79% or more, 81% or more, 83% or more, 85% or more, 87% or more, or 89% or more and/or 98% or less, 96% or less, or 94% or less, 92% or less, or 90% or less.

As for the infrared absorbing substrate, a substrate showing a maximum transmittance of 80% or more within the wavelength range of 425 nm to 560 nm can be used. In another examples, the maximum transmittance may be within the range of 82% or more, 84% or more, 86% or more, 88% or more, or 90% or more and/or 100% or less, 98% or less, 96% or less, 94% or less, 92% or less, or 90% or less.

As for the infrared absorbing substrate, a substrate showing an average transmittance of 75% or more within a wavelength range of 350 nm to 390 nm can be used. In another examples, the average transmittance may be within the range of 77% or more, 79% or more, 81% or more, or 83% or more and/or 98% or less, 96% or less, 94% or less, 92% or less, 90% or less, 88% or less, 86% or less, or 84% or less.

As for the infrared absorbing substrate, a substrate showing a maximum transmittance of 80% or more within the wavelength range of 350 nm to 390 nm can be used. In another examples, the maximum transmittance may be within the range of 82% or more, 84% or more, 86% or more, or 87% or more and/or 100% or less, 98% or less, 96% or less, 94% or less, 92% or less, 90% or less, or 88% or less.

As for the infrared absorbing substrate, a substrate having a transmittance in the range of 10% to 45% at a wavelength of 700 nm can be used. In another examples, the transmittance may be about 43% or less, 41% or less, 39% or less, 37% or less, 35% or less, 33% or less, 31% or less, or 29% or less, or 12% or more, 14% or more, 16% or more, 18% or more, 20% or more, 22% or more, 24% or more, 26% or more, or 28% or more.

As for the infrared absorbing substrate, a substrate exhibiting an average transmittance of 5% to 30% range within a wavelength range of 700 nm to 800 nm can be used. In another examples, the average transmittance may be within the range of 7% or more, 9% or more, 11% or more, 13% or more, 15% or more, 15.5% or more, 16% or more, or 16.5% or more and/or 28% or less, 26% or less, 24% or less, 22% or less, 20% or less, 18% or less, or 17% or less.

As for the infrared absorbing substrate, a substrate exhibiting a maximum transmittance of 10% to 45% range within the wavelength range of 700 nm to 800 nm can be used. In another examples, the maximum transmittance may be within the range of 12% or more, 14% or more, 16% or more, 18% or more, 20% or more, 22% or more, 24% or more, 26% or more, or 28% or more and/or 43% or less, 41% or less, 39% or less, 37% or less, 35% or less, 33% or less, 31% or less, or 29% or less.

As for the infrared absorbing substrate, a substrate exhibiting an average transmittance of 3% to 20% range within a wavelength range of 800 nm to 1,000 nm can be used. In another examples, the average transmittance may be further adjusted within the range of 5% or more, 7% or more, 9% or more, or 11% or more and/or 18% or less, 16% or less, 14% or less, or 12% or less.

As for the infrared absorbing substrate, a substrate exhibiting a maximum transmittance of 5% to 30% range within the wavelength range of 800 nm to 1,000 nm can be used. In another examples, the maximum transmittance may be within the range of 7% or more, 9% or more, 11% or more, 13% or more, or 15% or more and/or 28% or less, 26% or less, 24% or less, 22% or less, 20% or less, 18% or less, or 16% or less.

As for the infrared absorption substrate, a substrate exhibiting an average transmittance of 10% to 50% range within a wavelength range of 1,000 nm to 1,200 nm can be used. In another examples, the average transmittance may be further adjusted within the range of 12% or more, 14% or more, 16% or more, 18% or more, 20% or more, 22% or more, 24% or more, or 25% or more and/or 48% or less, 46% or less, 44% or less, 42% or less, 40% or less, 38% or less, 36% or less, 34% or less, 32% or less, 30% or less, 28% or less, or 26% or less.

The infrared absorbing substrate may have a transmission band showing a maximum transmittance of 10% to 70% range within the wavelength range of 1,000 nm to 1,200 nm., In another examples, the maximum transmittance may be 12% or more, 14% or more, 16% or more, 18% or more, 20% or more, 22% or more, 24% or more, 26% or more, 28% or more, 30% or more, 32% or more, 34% or more, or 36% or more and/or 68% or less, 66% or less, 64% or less, 62% or less, 60% or less, 58% or less, 56% or less, 54% or less, 52% or less, 50% or less, 48% or less, 46% or less, 44% or less, 42% or less, 40% or less, 38% or less, or 37% or less.

An infrared absorbing substrate having the above characteristics can be combined with the absorption membrane to form a desired optical filter. As such a substrate, a substrate known as so-called infrared absorbing glass can be used. Such glass is an absorption-type glass manufactured by adding CuO or similar content to fluorophosphate-based glass or phosphate-based glass. Therefore, in one example, a CuO-containing fluorophosphate glass substrate or a CuO-containing phosphate glass substrate may be used as the infrared absorbing substrate. The phosphate glass also includes K-phosphate glass where a portion of the glass frame is composed of SiO₂. Such the absorption-type glass is publicly known, and for example, the glass disclosed in Korean Patent No. 10-2056613 or other commercially available absorption-type glass (for example, commercially available products from Hoya, Schott, PTOT, etc.) can be used.

The infrared absorbing substrate contains copper. A substrate having a copper content in a range of 1% to 7% by weight can be used. In another examples, the copper content may be about 1.5% by weight or more, 2% by weight or more, 2.5% by weight or more, 2.6% by weight or more, 2.7% by weight or more, or 2.8% by weight or more or 6.5% by weight or less, 6% by weight or less, 5.5% by weight or less, 5% by weight or less, 4.5% by weight or less, 4% by weight or less, 3.5% by weight or less, 3% by weight or less, or 2.9% by weight or less. The substrate having such a copper content is likely to exhibit the above-mentioned optical properties and it can be combined with the absorption membrane to form an optical filter with desired properties.

The copper content can be confirmed by using X-ray fluorescence analysis equipment (WD XRF, Wavelength Dispersive X-Ray Fluorescence Spectrometry). When X-rays are irradiated to a specimen (substrate) using the equipment, characteristic secondary X-rays are generated from individual elements of the specimen and then, the equipment detects the secondary X-rays according to the wavelength of each element. The intensity of the secondary X-rays is proportional to the element content, and therefore, quantitative analysis can be performed through the intensity of the secondary.

The thickness of the infrared absorbing substrate may be adjusted within a range of, for example, about 0.03 mm to 5 mm, but is not limited to.

The optical filter may include other publicly known components required in addition to the substrate and the absorption membrane. For example, the optical filter may further include a dielectric membrane. For example, the dielectric membrane may additionally include a so-called dielectric membrane on one or both sides of the substrate.

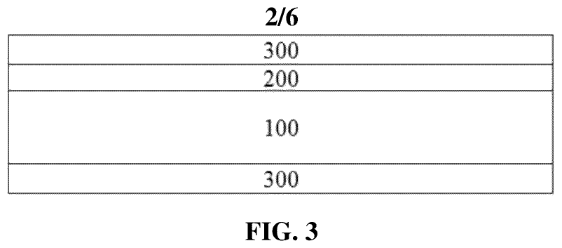

FIGS. 2 and 3 are examples of optical filters to which a dielectric membrane 300 is added. They illustrate a case where the dielectric membrane 300 is formed on one or both sides of a stacked structure including a substrate 100 and an absorption membrane 200.

The dielectric membrane is a membrane composed of repeatedly stacking dielectric material with a low refractive index and dielectric material with a high refractive index. It also is used to form a so-called IR reflection layer and an anti-reflection (AR) layer. A dielectric membrane may be applied for forming such a publicly know IR reflection layer or an AR layer.

Accordingly, the dielectric membrane may have a multi-layer structure including at least two types of sub-layers each having a different refractive index and may include a multi-layer structure where the two types of sub-layers are repeatedly stacked.

The type of material forming the dielectric membrane, in other words, the material forming each sub-layer is not particularly limited and known materials can be applied. Usually, fluorides such as SiO₂ or Na₅Al₃Fl₄, Na₃AlF₆ or MgF₂ are used to manufacture low-refractive sub-layers and amorphous silicon, TiO₂, Ta₂O₅, Nb₂O₅, ZnS, or ZnSe etc. may be used to manufacture high-refractive sub-layers, but the applied materials are not limited to the above.

The method of forming the above dielectric membrane is not particularly limited, and for example, it can be formed by applying a known deposition method. In the industry, there is a known method of controlling the reflection or transmission characteristics of the dielectric membrane in consideration of the deposition thickness or number of layers of the sub-layer and thus, the dielectric membrane can be formed according to this known method.

In one example, the dielectric membrane included in the optical filter may have a shortest wavelength of 710 nm or longer that exhibits a reflectance of 50% within a wavelength range of 600 nm to 900 nm or the wavelength may not exist. Additionally, when the wavelength does not exist, the maximum reflectance of the dielectric membrane is less than 50% in the wavelength range of 600 nm to 900 nm. The shortest wavelength that exhibits a reflectance of 50%, if present, may be, in another examples, about 715 nm or longer, 720 nm or longer, 725 nm or longer, 730 nm or longer, 735 nm or longer, 740 nm or longer, 745 nm or longer, 750 nm or longer, or 754 nm or longer. Alternatively, it may be about 900 nm or shorter, 850 nm or shorter, 800 nm or shorter, 790 nm or shorter, 780 nm or shorter, 770 nm or shorter, or 760 nm or shorter. The shortest wavelength representing the reflectance of 50% may be within a range of a lower limit and an upper limit among the lower limits described above, and in this case, the upper limit may be 900 nm.

By controlling the reflection characteristics of the dielectric membrane as described above, the so-called petal flare phenomenon can be prevented. The petal flare phenomenon refers to a phenomenon where a red line that is not observed with the naked eye is captured in a photograph when photographing a luminous object, etc. It is called as a petal flare phenomenon because the red line often takes on a shape like a flower petal based on the luminous object. As the sensitivity of a sensor included in an image capturing device is increased and the transmittance of an optical filter is increased to obtain clearer pictures, the frequency of occurrence of the petal flare is also increasing.

One of the causes of the petal flare phenomenon can be considered due to repeated reflection of near-infrared light within an image capturing device equipped with an optical filter. Among the dielectric membranes usually formed in the optical filter, a so-called IR membrane in particular is formed to block light in the near-infrared region by reflection. As a result, the shortest wavelength where the dielectric membrane exhibits a reflectance of 50% is formed near visible light, which is usually shorter than 710 nm. However, the reflection of near-infrared light within the image capturing device is accelerated by the dielectric membrane, the petal flare phenomenon occurs accordingly. However, if the shortest wavelength where the dielectric membrane exhibits a reflectance of 50% is adjusted to 710 nm or higher, the infrared light blocking efficiency of the optical filter is decreased.

However, through the application of the absorption membrane, infrared light can be effectively blocked even when the shortest wavelength where the dielectric membrane exhibits a reflectance of 50% is adjusted to 710 nm or higher and the petal flare phenomenon can also be prevented. Meanwhile, the design method itself for controlling the reflection characteristics of the dielectric membrane is publicly known.

The optical filter may further include an absorption membrane (referred to as an ultraviolet absorption membrane) that exhibits absorption characteristics for ultraviolet rays as an absorption membrane that is distinct from the absorption membrane. However, the UV absorption membrane is not an essential component, and for example, an ultraviolet absorbent described later may be introduced into one absorption membrane together with the compounds of Formulas 1 and 2, etc.

In one example, the ultraviolet absorption membrane may be designed to exhibit an absorption maximum in a wavelength range of about 300 nm to 390 nm. The ultraviolet absorption membrane may contain only a ultraviolet absorbent, or, if necessary, may include two or more types of ultraviolet absorbents. For example, as for the ultraviolet absorbent, a publicly known absorbent that exhibits maximum absorption in the wavelength range of about 300 nm to 390 nm can be used. For example, the UV absorbent may include ABS 407 from Exiton; UV381A, UV381B, UV382A, UV386A, and VIS404A from QCR Solutions Corp; HW Sands' ADA1225, ADA3209, ADA3216, ADA3217, ADA3218, ADA3230, ADA5205, ADA3217, ADA2055, ADA6798, ADA3102, ADA3204, ADA3210, ADA2041, ADA3201, ADA3202, ADA3215, ADA3219, ADA3225, ADA3232, ADA4160, ADA5278, ADA5762, ADA6826, ADA7226, ADA4634, ADA3213, ADA3227, ADA5922, ADA5950, ADA6752, ADA7130, ADA8212, ADA2984, ADA2999, ADA3220, ADA3228, ADA3235, ADA3240, ADA3211, ADA3221, ADA5220, and ADA7158; and CRYSTALYN's DLS 381B, DLS 381C, DLS 382A, DLS 386A, DLS 404A, DLS 405A, DLS 405C, and DLS 403A, etc., but are not limited to.

The materials and configuration methods used to construct this ultraviolet absorption membrane are not particularly limited, and publicly known materials and configuration methods can be applied. Typically, an ultraviolet absorption membrane is formed by using material mixed with a transparent resin and an ultraviolet absorbent capable of exhibiting the desired absorption maximum. At this time, the transparent resin may be a resin component applied to the absorbent composition. In addition to the layers described above, an optical filter may be added to the extent that various necessary layers do not impair the desired effect.

The present specification also discloses an imaging device including the optical filter. At this time, the configuration of the imaging device or the application method of the optical filter is not particularly limited, and known configurations and application methods may be applied. In addition, the use of the optical filter is not limited to the image capturing device. The optical filter can be applied to various other applications that require near-infrared ray cutting (for example, display devices such as PDPs, etc.).

The present specification also discloses an infrared sensor including the absorption membrane. The configuration of the infrared sensor is not particularly limited as long as the absorption membrane is included. For example, it can be configured by introducing the absorption membrane into a known motion sensor, proximity sensor, or gesture sensor. In addition, the use of the absorbent composition, resin composition, or resin membrane (absorption membrane) is not limited to the optical filter, infrared sensor, and/or image capturing device and is for various other applications requiring infrared cutting (e.g., a display device such as a PDP, etc.).

### Specific Details for Carrying Out the Invention

The composition, etc. will be described in detail through examples stated below, but the scope of the composition, etc., is not limited by the examples below. Moreover, various substitutions, modifications, and changes are possible for those skilled in the art within the technical scope of the present invention. The effects that can be obtained from the present invention are not limited to the effects mentioned above, and other effects not mentioned can be clearly understood by those skilled in the art from the description above.

### 1. Evaluation of Transmittance Spectrum

The transmittance spectrum was measured by using a spectrophotometer (Perkinelmer, Lambda750 spectrophotometer) on a specimen obtained by cutting the measurement object (for example, an absorption membrane) so that the width and height were 10 mm and 10 mm, respectively. Transmittance spectra were measured for each wavelength and the incident angle according to the equipment manual. The specimen was placed on a straight line between the measuring beam of the spectrophotometer and the detector and the transmittance spectrum was evaluated by setting the incident angle of the measuring beam to 0°. The incident angle of 0° is a direction substantially parallel to the surface normal direction of the specimen. The average transmittance within a certain wavelength range in the transmittance spectrum is the result of measuring the transmittance at each wavelength while increasing the wavelength by 1 nm starting from the shortest wavelength in the wavelength range, and then calculating the arithmetic average of the measured transmittances. The minimum transmittance is the minimum transmittance among the transmittances measured while increasing the wavelength by 1 nm and the maximum transmittance is the maximum transmittance among the transmittances measured while increasing the wavelength by 1 nm. For example, the average transmittance within a wavelength range of 350 nm to 360 nm is the arithmetic mean of the transmittance measured at the wavelength of 350 nm, 351 nm, 352 nm, 353 nm, 354 nm, 355 nm, 356 nm, 357 nm, 358 nm, 359 nm, and 360 nm. The maximum transmittance within the wavelength range of 350 nm to 360 nm is the highest transmittance measured at wavelengths of 350 nm, 351 nm, 352 nm, 353 nm, 354 nm, 355 nm, 356 nm, 357 nm, 358 nm, 359 nm and 360 nm and the minimum transmittance within the wavelength range of 350 nm to 360 nm is the lowest transmittance among the transmittances measured at wavelengths of 350 nm, 351 nm, 352 nm, 353 nm, 354 nm, 355 nm, 356 nm, 357 nm, 358 nm, 359 nm, and 360 nm.

### 2. Mass Analysis

Mass analysis of the synthesized compounds was performed by using a liquid chromatograph/mass spectrometry instrument (manufactured by Thermo Finnigan Co., Ltd.).

### Synthesis Example 1: Preparation of Compound 1A

The compound of Chemical Formula 1A (Compound 1A) in Chemical Reaction Formula 1 below was synthesized in the following manner.

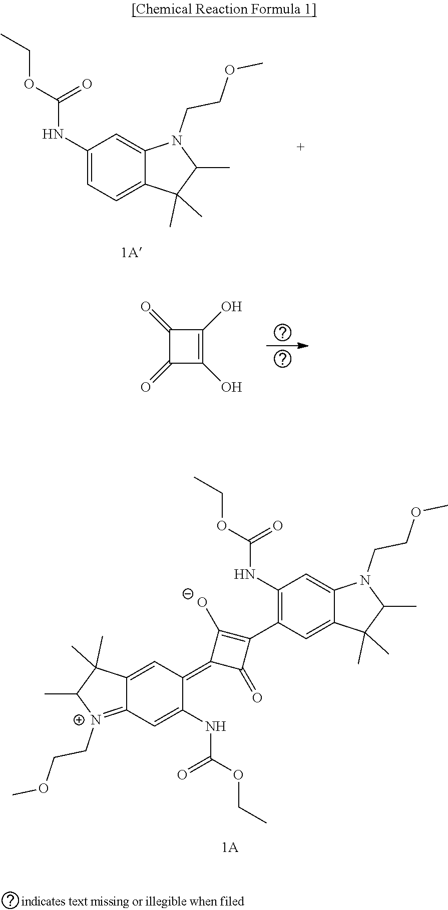

14.1 g of Compound 1A′ in Chemical Reaction Formula 1, 2.62 g of Squaric acid, and 8.7 g of tetraethyl orthoformate (TEOF) were dissolved in 100 mL of solvent (n-Butanol) and reacted at 95° C. for about 4 hours. After the reaction was cooled to room temperature (about 25° C.), 300 mL of ethanol was added, and after further stirring for more than 6 hours, the precipitated solid was passed through ethanol and filtered under reduced pressure. As a result, the target product (Compound 1A of Formula 1A) (7.4 g, 46%) was obtained.

The mass analysis results for the synthesized target compound (Compound 1A of Formula 1A) are as follow:

### <Mass Analysis Results>

LC-MS m/z 690.5

### Synthesis Example 2: Preparation of Compound 1B

In Chemical Reaction Formula 2, the compound of Chemical Formula 1B (Compound 1B) was synthesized through the same process as in Chemical Reaction Formula 1 except that Compound 1B′ was used in an amount of 10.2 g instead of Compound 1A′.

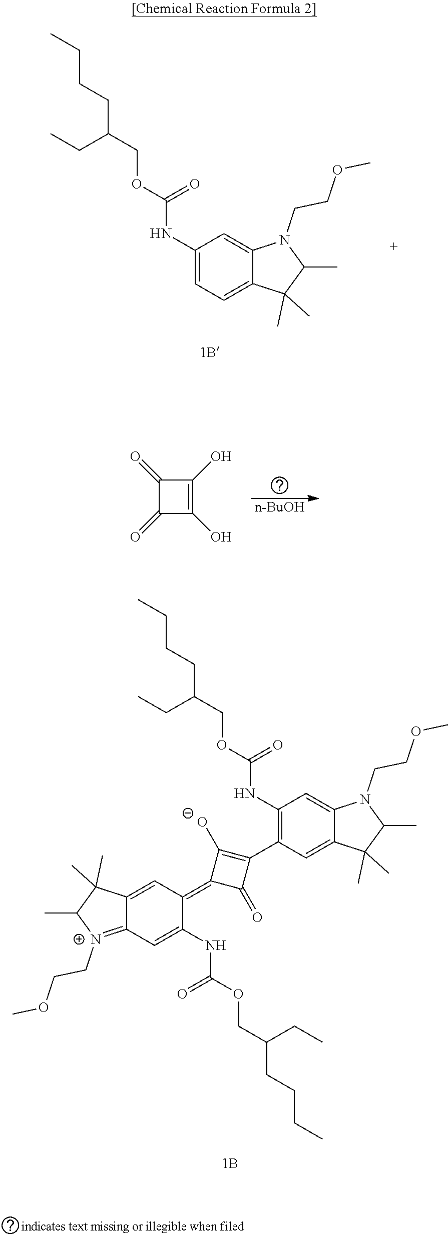

The mass analysis results for the synthesized target compound (Compound 1B of Formula 1B) are as follow:

### <Mass Analysis Results>

LC-MS m/z 859.1

### Synthesis Example 3: Preparation of Compound 1C

In Chemical Reaction Formula 3, the compound of Chemical Formula 1C (Compound 1C) was synthesized through the same process as in Chemical Reaction Formula 1 except that 5.3 g of Compound 1C′ was used instead of Compound 1A′.

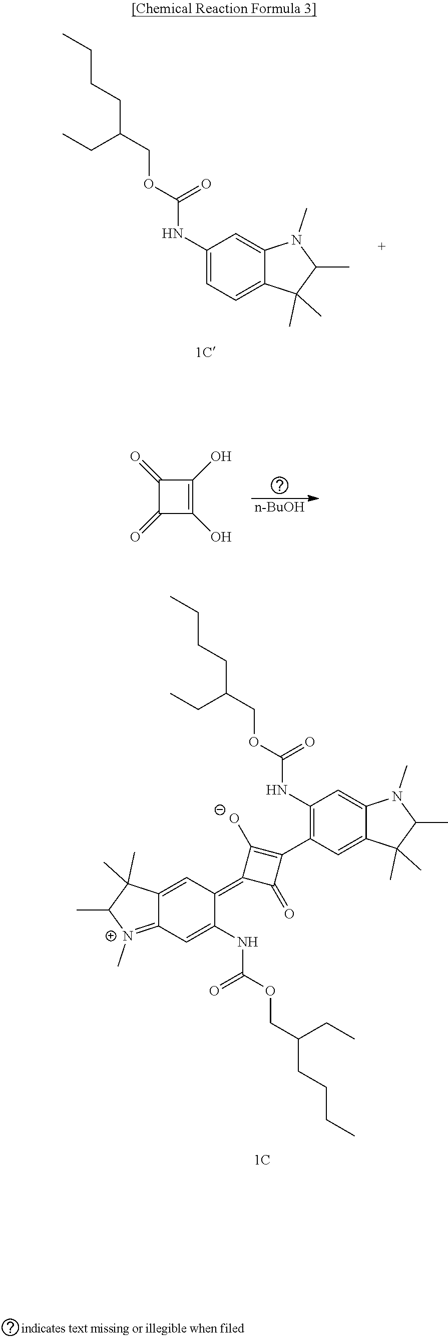

The mass analysis results for the synthesized target compound (Compound 1C of Formula 1C) are as follows:

### <Mass Analysis Results>

LC-MS m/z 771.0

### Synthesis Example 4: Preparation of Compound 1D

In Chemical Reaction Formula 4, the compound of Chemical Formula 1D (Compound 1D) was synthesized through the same process as in Chemical Reaction Formula 1 except that 10.8 g of Compound 1D′ was used instead of Compound 1A′.

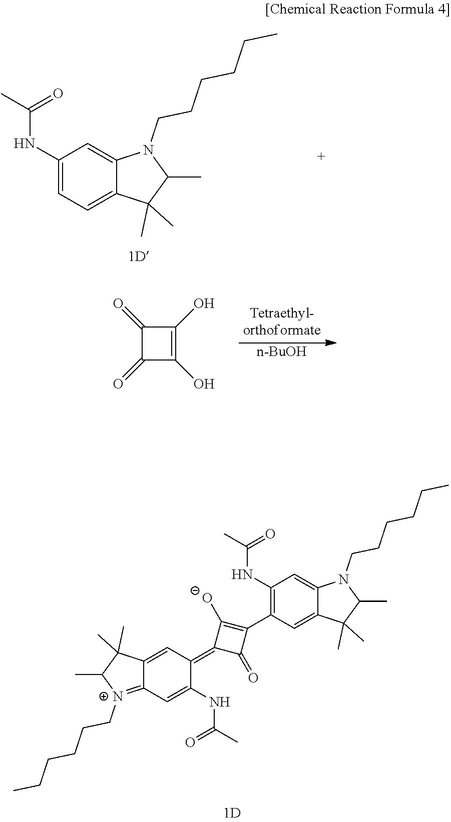

The mass analysis results for the synthesized target compound (compound 1D of Formula 1D) are as follows:

### <Mass Analysis Results>

LC-MS m/z 682.9

### Synthesis Example 5: Preparation of Compound 1E

In Chemical Reaction Formula 5, the compound of Chemical Formula 1E (Compound 1E) was synthesized through the same process as in Chemical Reaction Formula 1 except that 8.5 g of Compound 1E′ was used instead of Compound 1A′.

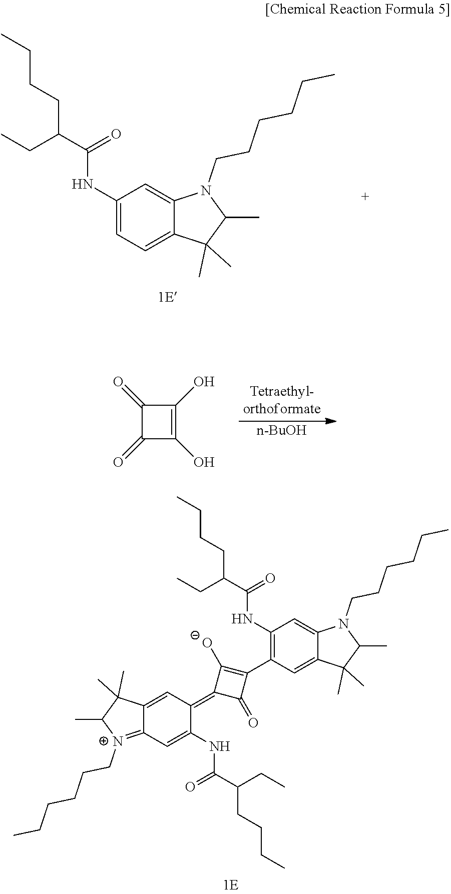

The mass analysis results for the synthesized target compound (compound 1E of Formula 1E) are as follows:

### <Mass Analysis Results>

LC-MS m/z 851.3

### Synthesis Example 6: Preparation of Compound 1F

In Chemical Reaction Formula 6, the compound of Chemical Formula 1F (Compound 1F) was synthesized through the same process as in Chemical Reaction Formula 1 except that Compound 1F′ was used in an amount of 6.4 g instead of Compound 1A′.

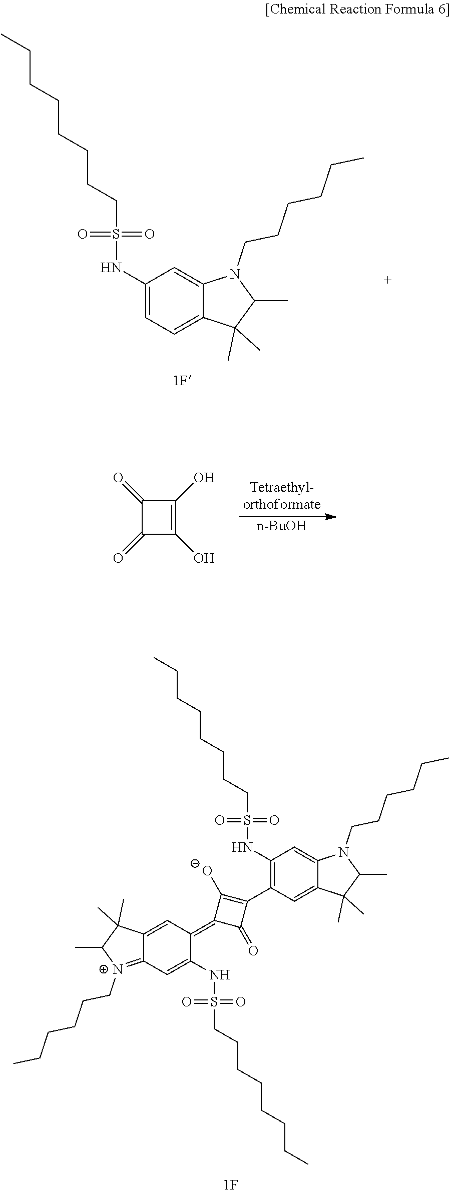

The mass analysis results for the synthesized target compound (compound 1F of Formula 1F) are as follows:

### <Mass Analysis Results>

LC-MS m/z 951.4

### Synthesis Example 7: Preparation of Compound 1AA

In Chemical Reaction Formula 7, the compound of Chemical Formula 1AA (Compound 1AA) was synthesized through the same process as in Chemical Reaction Formula 1 except that Compound 1AA′ was used in an amount of 9.7 g instead of Compound 1A′.

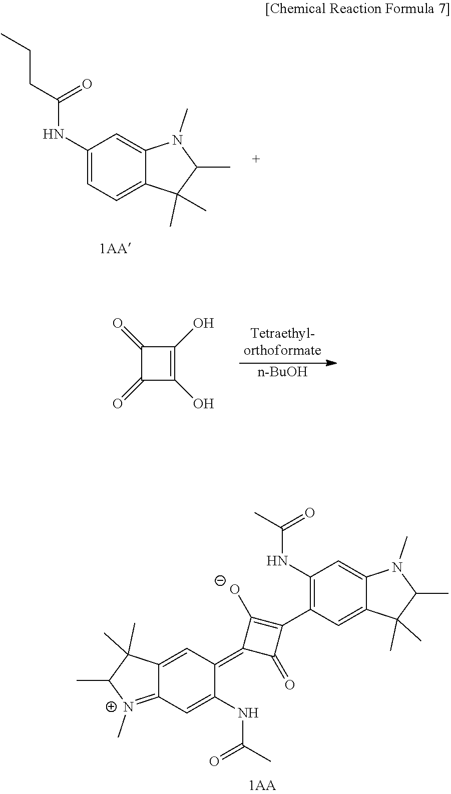

The mass analysis results for the synthesized target compound (Compound 1AA of Formula 1AA) are as follows:

### <Mass Analysis Results>

LC-MS m/z 542.3

### Synthesis Example 8: Preparation of Compound 2A

The compound of Chemical Formula 2A (Compound 2A) in Chemical Reaction Formula 8 below was synthesized in the following manner.

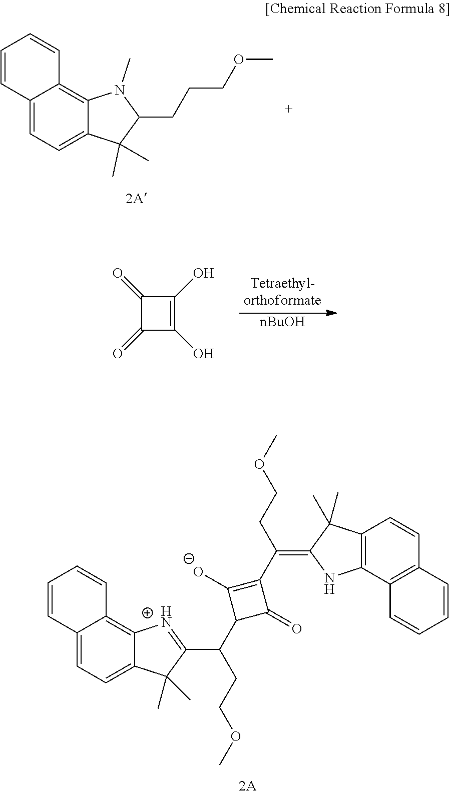

10.1 g of Compound 2A′ in Chemical Reaction Formula 2, 2.2 g of Squaric acid, and 7.8 g of tetraethyl orthoformate (TEOF) were dissolved in 100 mL of solvent (n-butanol) and reacted at 95° C. for 4 hours. After the reaction, cool to room temperature (about 25° C.), add 300 mL of ethanol, stir for more than 6 hours, and filter the precipitated solids under reduced pressure through ethanol. As a result, the target product (Compound 2A of Formula 2A) (6.8 g, 58%)) was obtained.

The mass analysis results for the synthesized target compound (Compound 2A of Formula 2A) are as follows:

### <Mass Analysis Results>

LC-MS m/z 612.2

### Synthesis Example 9: Preparation of Compound 2B

In Chemical Reaction Formula 9, the compound of Chemical Formula 2B (Compound 2B) was synthesized through the same process as in Chemical Reaction Formula 8 except that Compound 2B′ was used in an amount of 6.4 g instead of Compound 2A′.

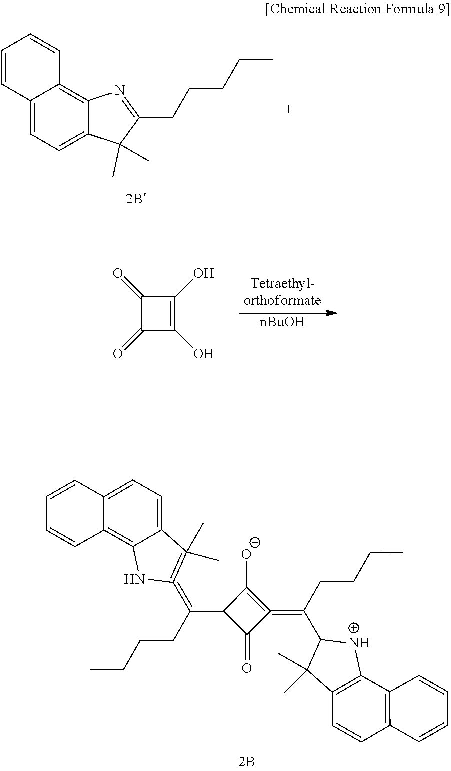

The mass analysis results for the synthesized target compound (Compound 2B of Formula 2B) are as follows:

### <Mass Analysis Results>

LC-MS m/z 608.7

### Synthesis Example 10: Preparation of Compound 2C

In Chemical Reaction Formula 10, the compound of Chemical Formula 2C (Compound 2C) was synthesized through the same process as in Chemical Reaction Formula 8 except that Compound 2C′ was used in an amount of 7.8 g instead of Compound 2A′.

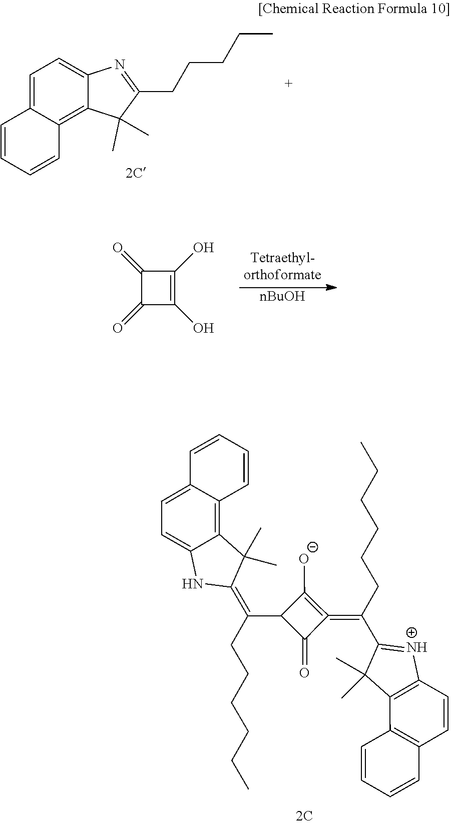

The mass analysis results for the synthesized target compound (Compound 2C of Formula 2C) are as follows:

### <Mass Analysis Results>

LC-MS m/z 664.9

### Synthesis Example 11: Preparation of Compound 2D

In Chemical Reaction Formula 11, the compound of Chemical Formula 2D (Compound 2D) was synthesized through the same process as in Chemical Reaction Formula 8 except that Compound 2D′ was used in an amount of 9.2 g instead of Compound 2A′.

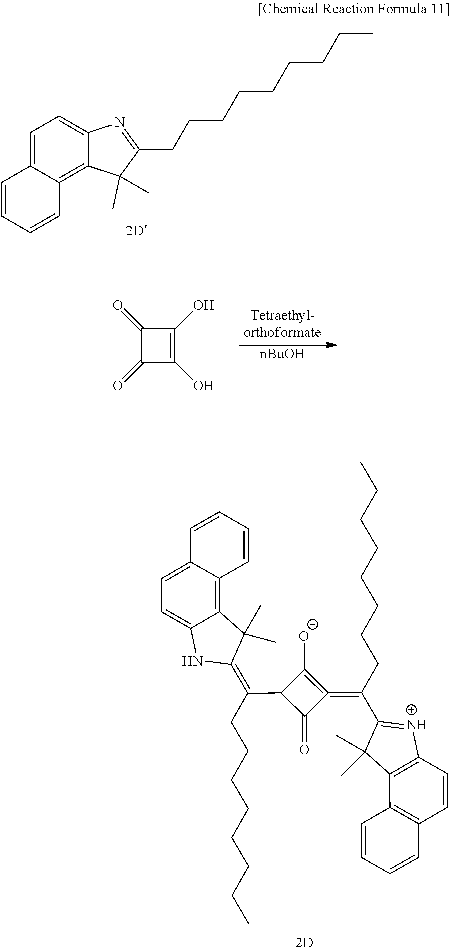

The mass analysis results for the synthesized target compound (Compound 2D of Formula 2D) are as follows:

### <Mass Analysis Results>

LC-MS m/z 721.1

### Synthesis Example 12: Preparation of Compound 2AA

In Chemical Reaction Formula 12, the compound of Chemical Formula 2AA (Compound 2AA) was synthesized through the same process as in Chemical Reaction Formula 8 except that Compound 2AA′ was used in an amount of 8.3 g instead of Compound 2A′.

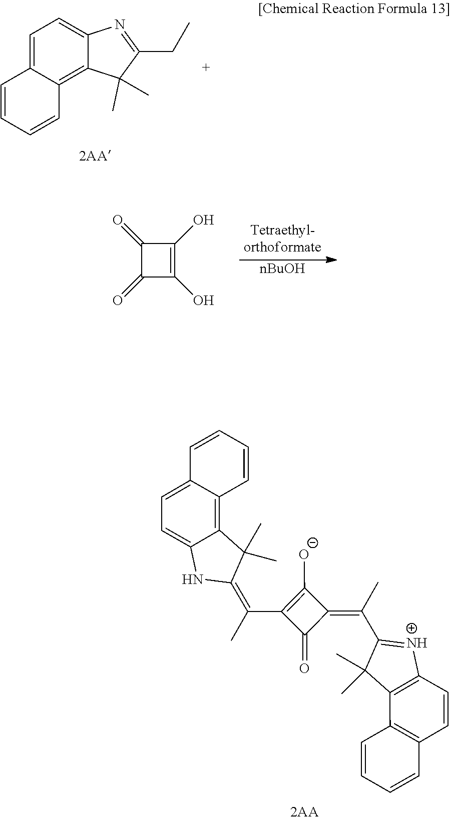

The mass analysis results for the synthesized target compound (Compound 2AA of Formula 2AA) are as follows:

### <Mass Analysis Results>

LC-MS m/z 524.3

### Synthesis Example 13: Preparation of Compound 3A

The compound of Chemical Formula 3A (Compound 3A) in Chemical Reaction Formula 13 was synthesized in the following manner.

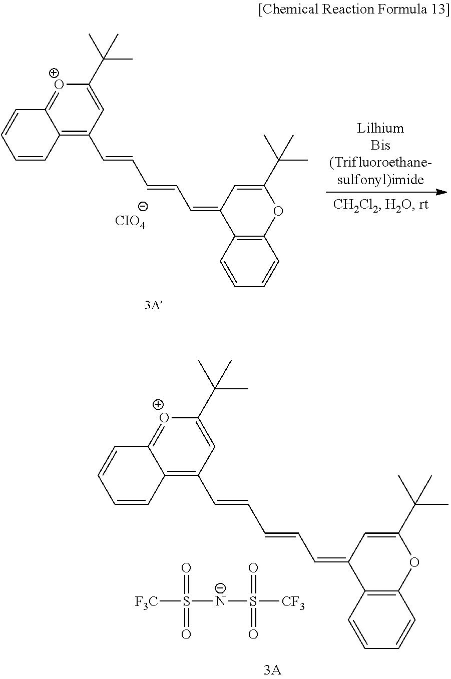

1.0. g of Compound 3A′ in Chemical Reaction Formula 13 (1.86 mmol) and 0.64 g (4.16 mmol) of LiTFSI (Lithium bis(trifluoromethane sulfonyl)imide) were dissolved in 20 mL of solvent (dichloromethane) and reacted at room temperature (25° C.) for about 2 hours after adding 20 mL of water. After the reaction, the dichloromethane layer and the water layer were separated by using an extractor, concentrated, added with 100 mL of ethanol, and filtered under reduced pressure. As a result, the target chemical (Compound 3A of Chemical Formula 3A) (1.0 g, 74.8%) was obtained.

The mass analysis results for the synthesized target compound (Compound 3A of Formula 3A) are as follows:

### <Mass Analysis Results>

LC-MS (+) m/z 437.8, LC-MS (−) m/z 287.9

### Synthesis Example 14: Preparation of Compound 3B

In Chemical Reaction Formula 14, the compound of Chemical Formula 3B (Compound 3B) was synthesized through the same process as in Chemical Reaction Formula 13 except that 1.4 g of Compound 3B′ was used instead of Compound 3A′.

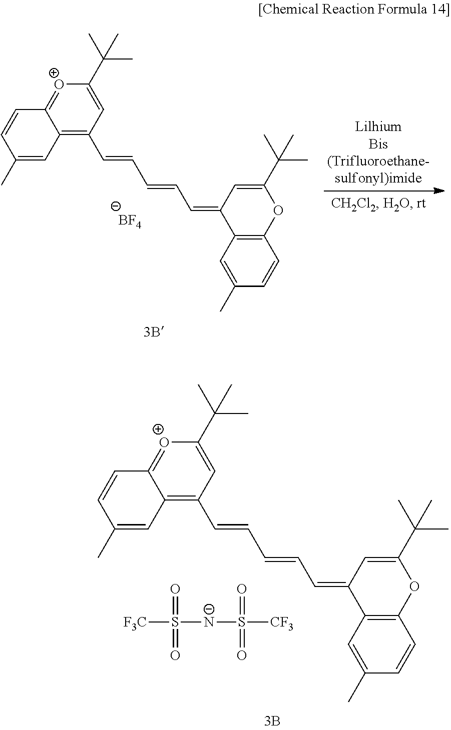

The mass analysis results for the synthesized target compound (Compound 3B of Formula 3B) are as follows:

### <Mass Analysis Results>

LC-MS (+) m/z 465.7, LC-MS (−) m/z 287.9

### Synthesis Example 15: Preparation of Compound 3C

In Chemical Reaction Formula 15, the compound of Chemical Formula 3C (Compound 3C) was synthesized through the same process as in Chemical Reaction Formula 13 except that Compound 3C′ was used in an amount of 1.3 g instead of Compound 3A′.

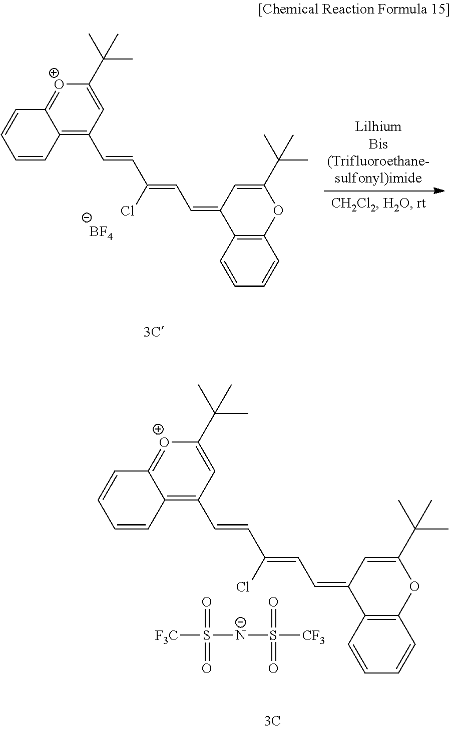

The mass analysis results for the synthesized target compound (Compound 3C of Formula 3C) are as follows:

### <Mass Analysis Results>

LC-MS (+) m/z 472.1, LC-MS (−) m/z 287.9

### Synthesis Example 16: Preparation of Compound 3D

In Chemical Reaction Formula 16, the compound of Chemical Formula 3D (Compound 3D) was synthesized through the same process as in Chemical Reaction Formula 13 except that Compound 3D′ was used in an amount of 1.0 g instead of Compound 3A′.

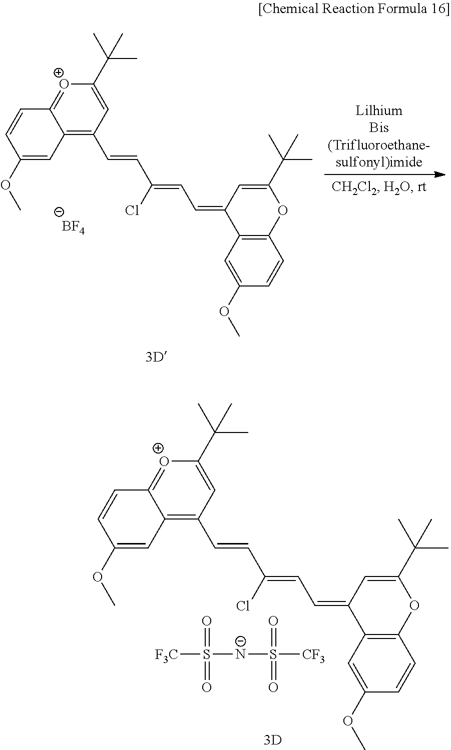

The mass analysis results for the synthesized target compound (Compound 3D of Formula 3D) are as follows:

### <Mass Analysis Results>

LC-MS (+) m/z 532.1, LC-MS (−) m/z 287.9

### Synthesis Example 17: Preparation of Compound 4A

In Chemical Reaction Formula 17, the compound of Chemical Formula 4A (Compound 4A) was synthesized through the same process as in Chemical Reaction Formula 13 except that Compound 4A′ was used in an amount of 1.1 g instead of Compound 3A′.

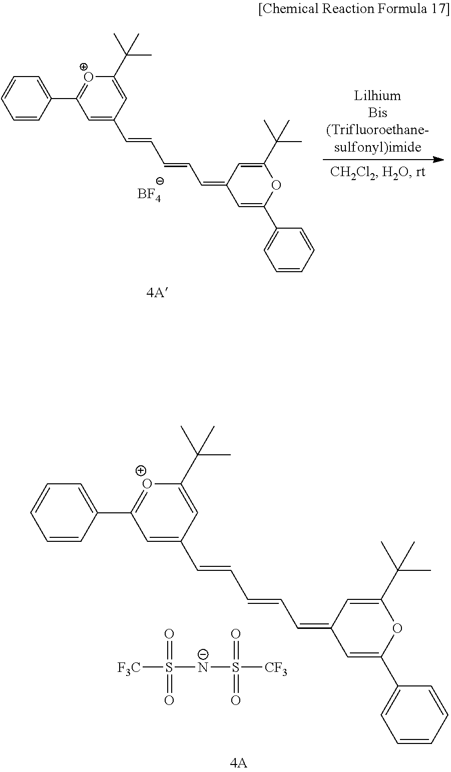

The mass analysis results for the synthesized target compound (Compound 4A of Formula 4A) are as follows:

### <Mass Analysis Results>

LC-MS (+) m/z 489.7, LC-MS (−) m/z 287.9

### Synthesis Example 18: Preparation of Compound 4B

In Chemical Reaction Formula 18, the compound of Chemical Formula 4B (Compound 4B) was synthesized through the same process as in Chemical Reaction Formula 13 except that 1.2 g of Compound 4B′ was used instead of Compound 3A′.

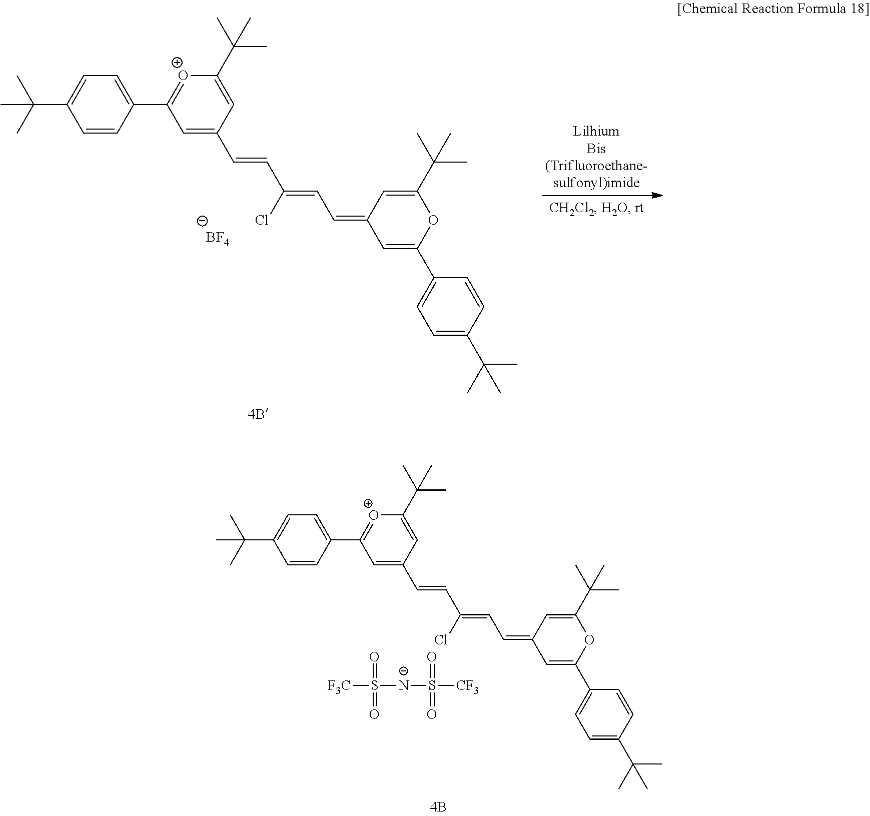

The mass analysis results for the synthesized target compound (Compound 4B of Formula 4B) are as follows:

### <Mass Analysis Results>

LC-MS (+) m/z 636.4, LC-MS (−) m/z 287.9

The solubility of each compound synthesized above was evaluated. Solubility was evaluated based on the following criteria by evaluating the solubility of each compound in multiple solvents (cyclohexanone, toluene, methyl isobutyl ketone (MIBK), or methyl ethyl ketone (MEK)) at room temperature (about 25° C.).

### 5<Solubility Evaluation Criteria>

A: A case where the solubility is 1% by mass or more.
B: A case where the solubility is 0.5 mass % or more and less than 1 mass %.
C: A case where the solubility is 0.2 mass % or more and less than 0.5 mass %.
D: A case where solubility is less than 0.2 mass %.

The solubility evaluation results are summarized in Table 1 below.

TABLE 1

| | Cyclohexanone | Toluene | MIBK | MEK |
|---|---|---|---|---|
| Synthesis | A | B | A | A |
| Example 1 | | | | |
| Synthesis | A | B | A | A |
| Example 2 | | | | |
| Synthesis | A | A | A | A |
| Example 3 | | | | |
| Synthesis | A | B | A | A |
| Example 4 | | | | |
| Synthesis | A | A | A | A |
| Example 5 | | | | |
| Synthesis | A | A | A | A |
| Example 6 | | | | |
| Synthesis | A | B | A | B |
| Example 7 | | | | |
| Synthesis | A | A | B | B |
| Example 8 | | | | |
| Synthesis | A | B | B | A |
| Example 9 | | | | |
| Synthesis | A | B | A | A |
| Example 10 | | | | |
| Synthesis | A | A | A | A |
| Example 11 | | | | |
| Synthesis | B | C | B | C |
| Example 12 | | | | |
| Synthesis | A | B | A | A |
| Example 13 | | | | |
| Synthesis | A | A | A | A |
| Example 14 | | | | |
| Synthesis | A | B | A | A |
| Example 15 | | | | |
| Synthesis | A | A | A | A |
| Example 16 | | | | |
| Synthesis | B | B | A | B |
| Example 17 | | | | |
| Synthesis | A | B | A | A |
| Example 18 | | | | |

### Embodiment 1

An absorbent composition was prepared by mixing Compound 1A of Synthesis Example 1, Compound 2B of Synthesis Example 9, and Compound 4A of Synthesis Example 17 at a weight ratio of about 55:40:40 (1A: 2B: 4A).

### Embodiment 2

An absorbent composition was prepared by mixing Compound 1B of Synthesis Example 2, Compound 2A of Synthesis Example 8, and Compound 4B of Synthesis Example 18 at a weight ratio of about 55:40:40 (1B: 2A: 4B).

### Embodiment 3

An absorbent composition was prepared by mixing Compound 1C of Synthesis Example 3, Compound 2C of Synthesis Example 10, and Compound 3D of Synthesis Example 16 at a weight ratio of about 55:40:40 (1C: 2C: 3D).

### Embodiment 4

An absorbent composition was prepared by mixing Compound 1D of Synthesis Example 4, Compound 2B of Synthesis Example 9, and Compound 3C of Synthesis Example 15 at a weight ratio of about 55:40:40 (1D: 2B: 3C).

### Embodiment 5

An absorbent composition was prepared by mixing Compound 1E of Synthesis Example 5, Compound 2D of Synthesis Example 11, and Compound 3B of Synthesis Example 14 at a weight ratio of about 55:40:40 (1E: 2D: 3B).

### Embodiment 6

An absorbent composition was prepared by mixing Compound 1F of Synthesis Example 6, Compound 2A of Synthesis Example 8, and Compound 3A of Synthesis Example 13 in a weight ratio of about 55:40:40 (1F: 2A: 3A).

### Comparative Example 1

An absorbent composition was prepared by mixing Compound 1AA of Synthesis Example 7, Compound 2AA of Synthesis Example 12, and Compound 4A of Synthesis Example 17 at a weight ratio of about 55:40:40 (1AA: 2AA: 4A).

The solubility of each absorbent composition in Embodiments and Comparative Examples was evaluated. Solubility is evaluated by injecting a resin composition prepared by dispersing the absorbent composition in a mixture containing a resin component and a solvent at room temperature (about 25° C.) by using a syringe filter with a filter size of about 1 μm according to the following criteria.

### <Solubility Evaluation Criteria>

A: A case where the absorbent composition passes well through the filter without clogging upon injection by the syringe filter.
B: A case where the absorbent composition passes through the filter, but the passage speed is significantly slowed due to clogging upon injection by the syringe filter.
C: A case where the absorbent composition does not pass through the filter upon injection by the syringe filter.

The evaluation results are summarized and listed in Table 2 below.

Condition 1 in Table 2 is a mixture (resin component+solvent) for preparing the resin composition where LG Chemical's acrylic resin (polymethylmethacrylate (PMMA)) is added to methyl isobutyl ketone (MIBK) at a concentration of about 15% by weight. Condition 2 is a mixture (resin component+solvent) where silicone resin (Dow Co., Ltd.) is dispersed in cyclohexanone at a concentration of about 15% by weight. Condition 3 is mixture (resin component+solvent) where cyclic olefin resin (TOPAS Co., Ltd.) dispersed in cyclohexanone at a concentration of about 15% by weight. When preparing each resin composition, the concentration of the absorbent composition in the resin composition was set to about 1.2% by weight.

TABLE 2

Solubility

| | Condition 1 | Condition 2 | Condition 3 |
|---|---|---|---|
| Embodiment 1 | B | B | B |
| Embodiment 2 | B | B | B |
| Embodiment 3 | A | B | A |
| Embodiment 4 | B | B | A |
| Embodiment 5 | A | B | A |
| Embodiment 6 | B | B | A |
| Comparative | C | C | B |
| Example 1 | | | |

### Embodiment 7

Acrylic resin (polymethylmethacrylate (PMMA)), the absorbent composition of Embodiment 3, and solvent (MIBK) were mixed at a weight ratio of 1.5:0.135:10 (Resin: Absorbent Composition: Solvent), and stirred for more than 12 hours to prepare a resin composition. As a result of evaluating the solubility as to this composition in the above manner, the evaluation result was A (a case where the absorbent composition passes well through the filter without clogging upon injection by the syringe filter).

The absorbent composition was spin-coated on a transparent substrate (SCHOTT Co., Ltd.) that substantially does not absorb or reflect light. Then, it was heat-treated at a temperature of about 130° C. for about 2 hours to form an absorption membrane with a thickness of about 3 μm.

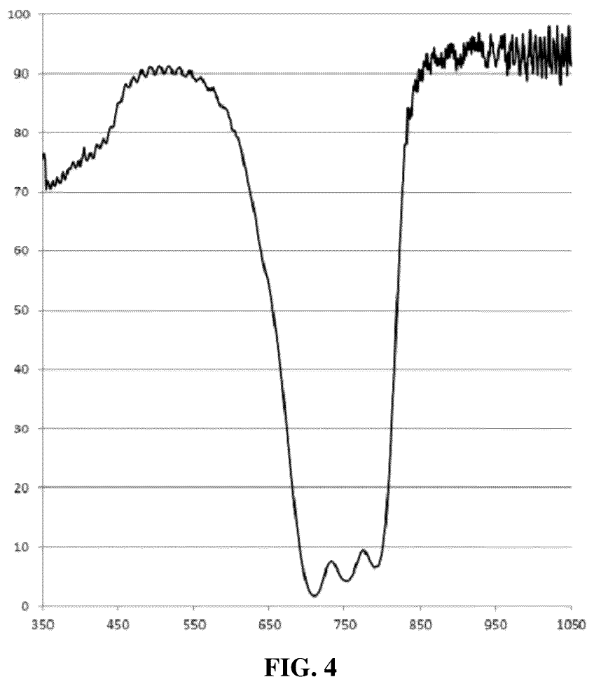

FIG. 4 is a diagram showing the results of evaluating the transmittance of the above absorption membrane. In the spectrum, the X-axis is the wavelength (nm) and the Y-axis is the transmittance.

### Embodiment 8

Cycloolefin polymer (COP), the absorbent composition of Embodiment 5, and the solvent (cyclohexanone) were mixed at a weight ratio of 1.5:0.135:10 (Resin: Absorbent Composition: Solvent) and stirred for more than 12 hours to prepare a resin composition. As a result of evaluating the solubility as to this composition in the above manner, the evaluation result was A (a case where the absorbent composition passes well through the filter without clogging upon injection by the syringe filter).

The absorbent composition was spin-coated on a transparent substrate (SCHOTT Co., Ltd.) that substantially does not absorb or reflect light. Then, it was heat-treated at a temperature of about 130° C. for about 2 hours to form an absorption membrane with a thickness of about 3 μm.

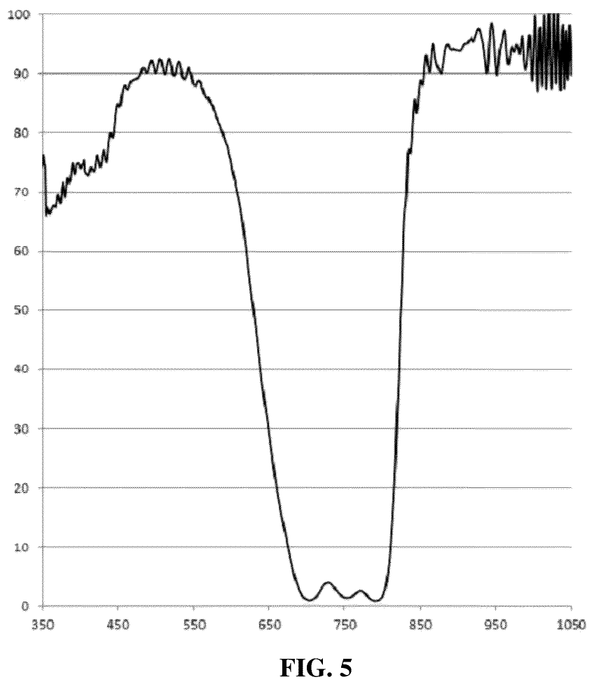

FIG. 5 is a spectrum showing the results of evaluating the transmittance of the above absorption membrane. In the spectrum, the X-axis is the wavelength (nm) and the Y-axis is the transmittance.

### Embodiment 9

The silicone resin, the absorbent composition of Embodiment 6, and the solvent (cyclohexanone) were mixed at a weight ratio of 1.5:0.135:10 (Resin: Absorbent Composition: Solvent) and stirred for more than 12 hours to prepare a resin composition. As a result of evaluating the solubility as to this composition in the above manner, the evaluation result was A (a case where the absorbent composition passes well through the filter without clogging upon injection by the syringe filter).

The absorbent composition was spin-coated on a transparent substrate (SCHOTT Co., Ltd.) that substantially does not absorb or reflect light. Then, it was heat-treated at a temperature of about 130° C. for about 2 hours to form an absorption membrane with a thickness of about 3 μm.

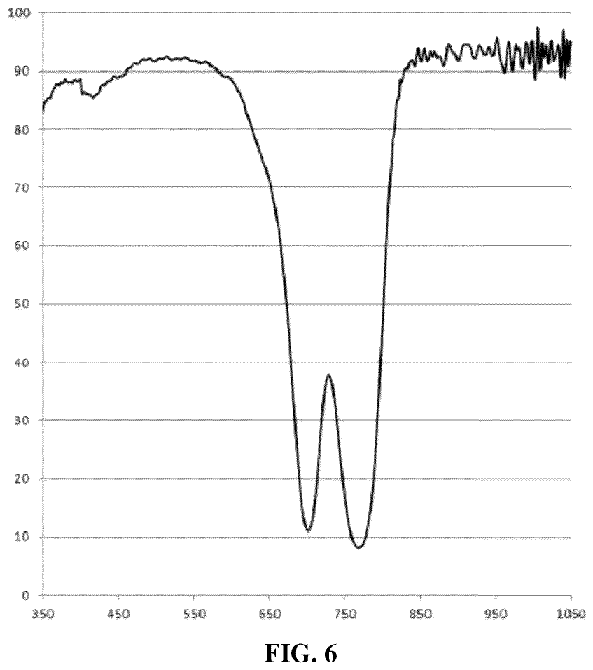

FIG. 6 is a spectrum showing the results of evaluating the transmittance of the above absorption membrane. In the spectrum, the X-axis is the wavelength (nm) and the Y-axis is the transmittance.

### Comparative Example 2

Cycloolefin polymer (COP) resin, the absorbent composition of Comparative Example 1, and the solvent (Cyclohexanone) were mixed at a weight ratio of 1.5:0.135:10 (Resin: Absorbent Composition: Solvent) and stirred for more than 12 hours to dissolve the resin to prepare a resin composition. As a result of evaluating the solubility as to this composition in the above manner, the evaluation result was A (a case where the absorbent composition passes well through the filter without clogging upon injection by the syringe filter).

The absorbent composition was spin-coated on a transparent substrate (SCHOTT Co., Ltd.) that substantially does not absorb or reflect light. Then, it was heat-treated at a temperature of about 130° C. for about 2 hours to form an absorption membrane with a thickness of about 3 μm.

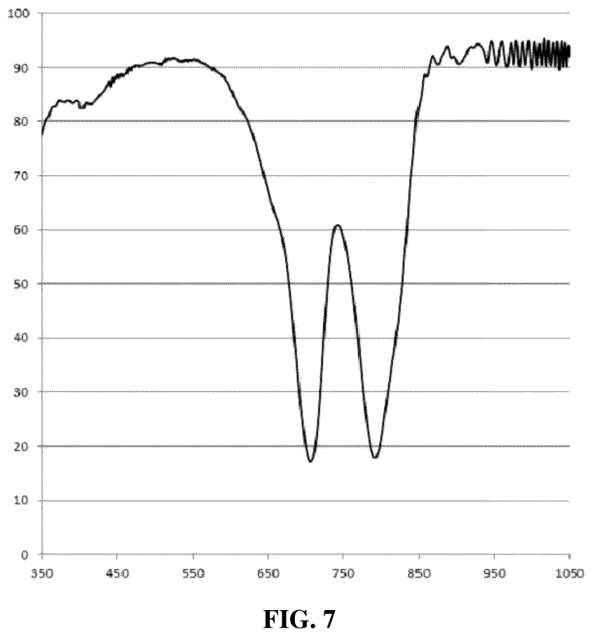

FIG. 7 is a spectrum showing the results of evaluating the transmittance of the above absorption membrane. In the spectrum, the X-axis is the wavelength (nm) and the Y-axis is the transmittance.

The absorption characteristics of the absorption membranes of Embodiments 7 to 9 and Comparative Example 2 were evaluated within the wavelength range of 600 nm to 900 nm. The results are summarized in Table 3 below.

In Table 3, T50% cut-on is the shortest wavelength showing a transmittance of 50% within the wavelength range of 600 nm to 900 nm in the transmittance spectrum. T50% cut-off is the longest wavelength showing a transmittance of 50% in the wavelength range of 600 nm to 900 nm in the transmittance spectrum. It is the longest wavelength with a transmittance of 50% within the wavelength range.

In Table 3, T20% cut-on is the shortest wavelength showing a transmittance of 20% within the wavelength range of 600 nm to 900 nm in the transmittance spectrum. T20% cut-off is the longest wavelength showing a transmittance of 20% in the wavelength range of 600 nm to 900 nm in the transmittance spectrum. It is the longest wavelength with a transmittance of 20% within the wavelength range.

In Table 3, T (MIN) is the minimum transmittance confirmed within the wavelength range of 600 nm to 900 nm. T (AVG) is the average transmittance within the wavelength range of 600 nm to 900 nm.

TABLE 3

| | | | | | Comparative |
|---|---|---|---|---|---|
| | | Embodiment 7 | Embodiment 8 | Embodiment 9 | Example 2 |
| T50% cut-on(nm) | | 655.0 | 629.4 | 673.0 | 678.2 |
| T50% cut-off (nm) | | 819.2 | 824.6 | 801.5 | 828.5 |
| T20% cut-on(nm) | | 681.1 | 660.0 | 689.9 | 699.6 |
| T20% cut-off (nm) | | 807.8 | 815.7 | 788.6 | 798.2 |
| 600 nm~900 nm | T(MIN)(%) | 1.6 | 0.8 | 8.0 | 17.1 |
| | T(AVG)(%) | 43.3 | 34.9 | 56.8 | 57.0 |

1. A composition comprising:
a first compound represented by Formula 1: 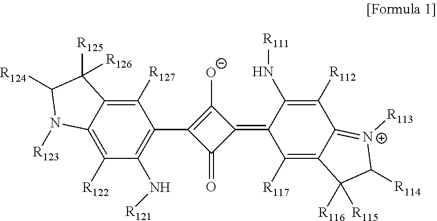
wherein
R₁₁₁ to R₁₁₇ and R₁₂₁ to R₁₂₇ are each independently hydrogen, an alkyl group, an alkyloxy group, an alkyloxyalkyl group, an alkylcarbonyl group, an alkyloxycarbonyl group, an alkyloxyalkylcarbonyl group, or an alkylsulfonyl group wherein at least one of R₁₁₁ to R₁₁₇ and R₁₂₁ to R₁₂₇ is the alkyl group, the alkyloxy group, the alkyloxyalkyl group, the alkylcarbonyl group, the alkyloxycarbonyl group, the alkyloxyalkylcarbonyl group, or the alkylsulfonyl group in Formula 1;
a second compound represented by Formula 2: 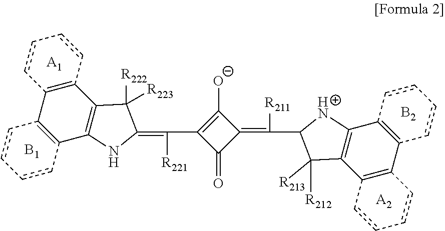
R₂₁₁ to R₂₁₃ and R₂₂₁ to R₂₂₃ are each independently hydrogen, an alkyl group, an alkyloxy group, an alkyloxyalkyl group, an alkylcarbonyl group, an alkyloxycarbonyl group, an alkyloxyalkylcarbonyl group, or an alkylsulfonyl group wherein at least one among R₂₁₁ to R₂₁₃ and R₂₂₁ to R₂₂₃ is the alkyl group, the alkyloxy group, the alkyloxyalkyl group, the alkylcarbonyl group, the alkyloxycarbonyl group, the alkyloxyalkylcarbonyl group, or the alkylsulfonyl group and A₁, B₁, A₂ and B₂ are each independently a benzene structure or absent in Formula 2; and
a third compound represented by Formula 3: 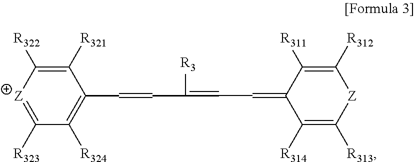
wherein
R₃ is hydrogen or halogen;
R₃₁₁, R₃₁₂, R₃₂₁ and R₃₂₃ are each independently hydrogen, an alkyl group, an alkyloxy group, an alkyloxyalkyl group, an alkylcarbonyl group, an alkyloxycarbonyl group, an alkyloxyalkylcarbonyl group, an alkylsulfonyl group, or an aryl group;
R₃₁₃ and R₃₁₄ are each independently hydrogen, an alkyl group, an alkyloxy group, an alkyloxyalkyl group, an alkylcarbonyl group, an alkyloxycarbonyl group, an alkyloxyalkylcarbonyl group, an alkylsulfonyl group, or an aryl group or are connected to each other to form a benzene structure;
R₃₂₃ and R₃₂₄ are each independently hydrogen, an alkyl group, an alkyloxy group, an alkyloxyalkyl group, alkylcarbonyl group, an alkyloxycarbonyl group, an alkyloxyalkylcarbonyl group, an alkylsulfonyl group, or an aryl group or are connected to each other to form a benzene structure;
at least one among R₃₁₁ to R₃₁₄ and R₃₂₁ to R₃₂₄ is an alkyl group, an alkyloxy group, an alkyloxyalkyl group, an alkylcarbonyl group, an alkyloxycarbonyl group, an alkyloxyalkylcarbonyl group, or an alkylsulfonyl group or includes Z wherein Z is a heteroatom in Formula 3,
wherein a sum of A, B, and C is 30 or more and a standard deviation of A, B, and C is 15 or less wherein A, B, and C are defined as follows:
A: a sum of carbon numbers of the alkyl group, the alkyl group of the alkyloxy group, the alkyl group of the alkyloxyalkyl group, the alkyl group of the alkylcarbonyl group, the alkyl group of the alkyloxycarbonyl group, the alkyl group of the alkyloxyalkylcarbonyl group, and the alkyl group of the alkylsulfonyl group in Formula 1;
B: a sum of carbon numbers of the alkyl group, the alkyl group of the alkyloxy group, the alkyl group of the alkyloxyalkyl group, the alkyl group of the alkylcarbonyl group, the alkyl group of the alkyloxycarbonyl group, the alkyl group of the alkyloxyalkylcarbonyl group, and the alkyl group of the alkylsulfonyl group in Formula 2; and
C: a sum of carbon numbers of the alkyl group, the alkyl group of the alkyloxy group, the alkyl group of the alkyloxyalkyl group, the alkyl group of the alkylcarbonyl group, the alkyl group of the alkyloxycarbonyl group, the alkyl group of the alkyloxyalkylcarbonyl group, and the alkyl group of the alkylsulfonyl group in Formula 3.

2. The composition of claim 1, wherein an average of A, B and C is in a range of 8 to 35.

3. The composition of claim 1, wherein a ratio A/B of A to B is in a range of 0.1 to 10, a ratio
B/C of B to C is in a range of 0.1 to 10, and a ratio A/C of A to C is in a range of 0.5 to 15.

4. The composition of claim 1, wherein at least one among R₁₁₁ to R₁₁₇ and R₁₂₁ to R₁₂₇ is the
alkyloxy group, the alkyloxyalkyl group, the alkylcarbonyl group, the alkyloxycarbonyl group, the alkyloxyalkylcarbonyl group, or the alkylsulfonyl group in Formular 1;
R₂₁₁ to R₂₁₃ and R₂₂₁ to R₂₂₃ are each independently hydrogen, the alkyl group, the alkyloxy group, or the alkyloxyalkyl group upon at least one of R₂₁₁ to R₂₁₃ and R₂₂₁ to R₂₂₃ being the alkyl group, the alkyloxy group, or the alkyloxyalkyl group in Formula 2; and
Z is oxygen and R₃₁₁, R₃₁₂, R₃₂₁ and R₃₂₂ are each independently hydrogen, the alkyl group, or the aryl group upon at least one of R₃₁₁, R₃₁₂, R₃₂₁ and R₃₂₃ being the alkyl group in Formula 3.

5. The composition of claim 4, wherein either A₁ or B₁ forms a benzene structure and either A₂ or B₂ forms a benzene structure.

6. The composition of claim 5, wherein the other one of A₁ and B₁ is absent and the other one of A₂ and B₂ is absent.

7. The composition of claim 4, wherein R₃₁₃ and R₃₁₄ in Formula 3 are connected to each other to form a benzene structure and R₃₂₃ and R₃₂₄ are linked together to form a benzene structure.

8. The composition of claim 4, wherein at least one of R₃₁₁, R₃₁₂, R₃₂₁ and R₃₂₃ is a branched
alkyl group.

9. A resin composition comprising:
a resin component; and the composition of claim 1.

10. The resin composition of claim 9 further comprising a solvent.

11. A resin membrane comprising:
a resin component; and the composition of claim 1.

12. The resin membrane of claim 11, wherein the resin membrane exhibits an absorption band
with a bandwidth of 60 nm or wider within a wavelength range of 600 nm to 900 nm.

13. The resin membrane of claim 12, wherein a T50% cut-on wavelength is within the range of 600 nm to 800 nm.

14. The resin membrane of claim 12, wherein a T50% cut-off wavelength is within a range of
700 nm to 900 nm.

15. The resin membrane of claim 11, wherein the resin component includes at least one or more selected from a group of a cycloolefin (COP) based resin, a polyester resin, a polyarylate resin, a polysulfone resin, a polyether sulfone resin, a polyparaphenylene resin, a polyarylene ether phosphine oxide resin, a polyimide resin, a polyetherimide resin, a polyamideimide resin, an acrylic resin, a polycarbonate resin, a polyethylene naphthalate resin, and a silicone resin.

16. An optical filter comprising:
a substrate and the resin membrane of claim 11 formed on one or both sides of the substrate.

17. The optical filter of claim 16 further comprising:
a dielectric membrane wherein the shortest wavelength exhibiting a reflectance of 50% within a wavelength range of 600 nm to 900 nm is 710 nm or longer or is absent.

18. A solid-state image capturing device comprising the optical filter of claim 16.

19. An infrared sensor comprising the resin membrane of claim 11.
